(19) United States
(12) Patent Application Publication
(10) Pub. No.: US 2014/0349469 A1
(43) Pub. Date: Nov. 27, 2014

(54) PROCESSING FOR ELECTROMECHANICAL SYSTEMS AND EQUIPMENT FOR SAME

(71) Applicant: QUALCOMM MEMS TECHNOLOGIES, INC., San Diego, CA (US)

(72) Inventors: Teruo Sasagawa, Los Gatos, CA (US); Sandeep K. Giri, Mountain View, CA (US); Ana R. Londergan, Santa Clara, CA (US); Shih-chou Chiang, Taoyuan City (TW)

(73) Assignee: QUALCOMM MEMS TECHNOLOGIES, INC., San Diego, CA (US)

(21) Appl. No.: 13/900,436

(22) Filed: May 22, 2013

(51) Int. Cl. C23C 16/455; B05D 1/00; B05C 11/10; C23C 16/458; C23C 16/46

(52) U.S. Cl. CPC C23C 16/455; C23C 16/458; C23C 16/46; B05C 11/1044; B05D 1/00
USPC 438/504; 118/715; 118/728; 118/725; 118/729; 156/345.29; 427/255.28; 427/250; 216/58

(57) ABSTRACT

This disclosure provides systems, methods and apparatus for processing multiple substrates in a processing tool. An apparatus for processing substrates can include a process chamber, a common reactant source, and a common exhaust pump. The process chamber can be configured to process multiple substrates. The process chamber can include a plurality of stacked individual subchambers. Each subchamber can be configured to process one substrate. The common reactant source can be configured to provide reactant to each of the subchambers in parallel. The common exhaust pump can be connected to each of the subchambers.

### TECHNICAL FIELD

This disclosure relates to equipment and methods for forming electromechanical systems.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Typically one of the last fabrication processes before packaging an electromechanical system apparatus is the removal of a sacrificial layer from underneath a movable layer to define the cavity through which the movable layer can move. The removal of the sacrificial layer is often referred to as a release etch. After release, the device is vulnerable and sensitive to damage during subsequent handling and processing.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus for processing substrates. The apparatus includes a process chamber configured to process multiple substrates. The process chamber includes a plurality of stacked individual subchambers. Each subchamber is configured to process one substrate. The apparatus includes a common reactant source configured to selectively provide a reactant to each of the subchambers in parallel. The apparatus includes a common exhaust pump selectively connected to each of the subchambers.

In some implementations, a cluster tool including two or more of the apparatus is provided. The cluster tool includes at least two of: a first processing chamber including a first plurality of subchambers in fluid communication with a common etchant source including a fluorine based etchant; a second processing chamber including a second plurality of subchambers in fluid communication with a common source of atomic layer deposition reactants, including a first common oxidizing source and a second common source including one of a semiconductor and a metal source; and a third processing chamber including a third plurality of subchambers in fluid communication with a common source of reactant to form a self-assembled monolayer (SAM).

One innovative aspect of the subject matter described in this disclosure can be implemented in an apparatus for processing electromechanical systems devices. The apparatus includes a process chamber configured to process multiple substrates, including a means for isolating the process chamber into a plurality of stacked individual subchambers. Each subchamber is configured to process one substrate. The apparatus includes a means for selectively providing a common reactant to each of the subchambers. The apparatus includes a common means for selectively exhausting each of the subchambers.

In some implementations, a cluster tool including two or more of the apparatus is provided. The cluster tool includes two or more of: a first processing chamber including a first plurality of subchambers, including means for removing sacrificial layers from the substrates; a second processing chamber including a second plurality of subchambers, including means for forming an ALD layer on the substrates; and a third processing chamber including a third plurality of subchambers, including means for forming a self-assembled monolayer (SAM) on the substrates.

One innovative aspect of the subject matter described in this disclosure can be implemented in a method of processing substrates. The method includes transferring multiple substrates into a process chamber, wherein the process chamber includes a plurality of stacked individual subchambers, each subchamber configured to process one substrate. The method includes exposing the substrates to a reactant provided from a reactant source commonly connected to each of the subchambers. The method includes exhausting the reactant from the subchambers through an exhaust commonly and selectively connected to each of the subchambers.

In some implementations, the method is performed in two or more process chambers. In such a method, exposing the substrates to the reactant includes two or more of: exposing the substrates to a vapor phase etchant; exposing the substrates to vapor phase reactants to form a thin film on the substrates by ALD, and exposing the substrates to vapor phase reactants to form a self-assembled monolayer (SAM) on the substrates.

One innovative aspect of the subject matter described in this disclosure can be implemented in a method of processing substrates. The method includes transferring multiple substrates into a process chamber, wherein the process chamber includes a plurality of stacked individual subchambers, each subchamber configured to process one substrate. The method includes closing an outlet valve connected upstream of a first subchamber and downstream of a buffer. The method includes opening an inlet valve positioned upstream of the buffer. The method includes flowing reactant from a reactant source through the inlet valve and into the buffer. The method includes closing the inlet valve after pressure within the buffer reaches a pressure threshold. The method includes opening the outlet valve while the inlet valve is closed, to flow a pressure-controlled dose of reactant from the buffer into the first subchamber.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8F show examples of cross-sectional schematic illustrations of various stages in a method of making an interferometric modulator.

FIG. 9A shows an example of a flow diagram illustrating a method for processing multiple substrates.

FIG. 9B shows an example of a flow diagram illustrating a method for processing multiple substrates.

FIG. 10A shows an example of a flow diagram illustrating a method of processing substrates.

FIG. 10B shows an example of a flow diagram illustrating a method of processing substrates.

FIG. 11 is a schematic cross section of an example of an apparatus for batch processing.

FIG. 12 is a schematic plan view of one example of an apparatus for batch processing.

FIG. 13 is a schematic plan view of another example of an apparatus for batch processing.

FIG. 14 is a schematic plan view of another example of an apparatus for batch processing.

FIGS. 15A-15C show schematic cross sections of a batch process chamber useful for batch cluster tools like those of FIGS. 11-14.

FIG. 16 shows a schematic cross section of an example of a batch process chamber, having connections to three different gas delivery systems configured for etching, atomic layer deposition (ALD) and self-assembled monolayer (SAM) deposition.

FIG. 17A is a schematic illustration of an example of a batch process chamber configured for release etching.

FIG. 17B is a schematic illustration of an example of a batch process chamber configured for ALD.

FIG. 17C is a schematic illustration of an example of a batch process chamber configured for SAM deposition.

FIG. 18A is a schematic cross section of an example of an apparatus for batch processing.

FIG. 18B is a schematic cross section of another example of an apparatus for batch processing.

FIGS. 18C and 18D are partial schematic cross sections of the apparatus for batch processing of FIG. 18B, showing different states of operation.

FIGS. 19A-19D are schematics of an examples of apparatuses for batch processing.

FIG. 20A is a partial schematic cross section of an example of a lift pin and substrate support structure for loading and unloading a substrate in a process chamber.

FIG. 20B is a schematic cross section of another example of a lift pin and substrate support structure for loading and unloading a substrate in a process chamber.

FIGS. 21A and 21B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (such as a video) or stationary (such as a still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (such as display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Processing electromechanical systems devices can include a release etch process to etch a portion of each device to form an internal cavity in the device. After release, an antistiction layer can be formed in the cavity to reduce stiction in the device. The antistiction layer can include a layer formed by atomic layer deposition (ALD). In some implementations, additional deposition of a self-assembled monolayer (SAM) formed on top of the ALD layer can provide even further anti-stiction properties over an ALD layer alone. In some implementations, the SAM layer can also be formed over an already-existing layer (such as an etch stop layer) in the device, in which case a SAM anti-stiction layer may be formed after release without an ALD process being used. Each of the release etch, deposition of the ALD layer, and deposition of the SAM can be implemented within a standalone process tool, or integrated into a cluster tool. “Batch process chamber” or “batch tool” as used herein, refers to a tool configured for processing multiple substrates. As will be appreciated from the implementations described herein, a batch process chamber can employ a single chamber; a single outer chamber with a single inner chamber, in which substrates are in open communication with one another and a common gas sources and exhaust; or a single outer chamber and multiple inner chambers with individual gas feeds for the inner chambers. Multiple batch process chambers of one or more of the above configurations can be integrated into a cluster tool with one or more common transfer chambers through which substrates can access the process chambers. “Batch processing” refers to a process in which multiple substrates are simultaneously processed in parallel with a process chamber.

Particular implementations of the subject matter described in this disclosure can be implemented to realize one or more of the following potential advantages. The use of batch reactors to process multiple substrates can lower the production costs by increasing the throughput of substrates (that is, substrates processed per hour) and limit exposure to contaminants for sensitive post-release devices. Furthermore, precautions such as controlled relative pressures among a transfer chamber and attached separate processing chambers can decrease the risk for contamination of the substrate between processes and cross contamination of the different processing gases used for the etch/release, ALD layer formation, and SAM formation. In some implementations the transfer chamber and attached separate processing chambers can reduce risk for contamination of the substrate by using a low vacuum pressure in the transfer chamber and in the process chambers after processing and prior to, and during, substrate transfer. In some implementations, the multiple substrates can be commonly processed in a “batch” in each separate processing chamber.

In some implementations, the multiple substrates can be processed in a plurality of processing subchambers within each separate processing chamber. A processing chamber with such subchambers can be part of a cluster tool, or part of a standalone process tool. Such a process tool can be configured for one or more of etch/release, ALD layer formation and SAM formation, or can be configured for other types of processing. Each processing subchamber can be configured to process a subset of the multiple substrates. In some implementations, each processing subchamber can be configured to process a single substrate. Lower impurities in the device cavity can result in improved electrical properties and device performance and stability. In some implementations, a common reactant source can be configured to provide a reactant to each of the subchambers in parallel, and a common exhaust pump can be connected to each of the subchambers. In some implementations, a manifold can provide flowpaths from the common source of reactant to each subchamber that are approximately equal. In some implementations, an accumulator can be positioned between the common reactant source and upstream of the subchambers. In some implementations, a pressure-controlled dose of reactant can be provided into each subchamber.

It can be challenging to achieve both uniformity of processing and efficiency for treatment of large format substrates, such as glass or plastic substrates employed in the flat panel display industry. By providing multiple subchambers fed in parallel, uniformity advantages of single substrate processing can be combined with the efficiencies of batch processing.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

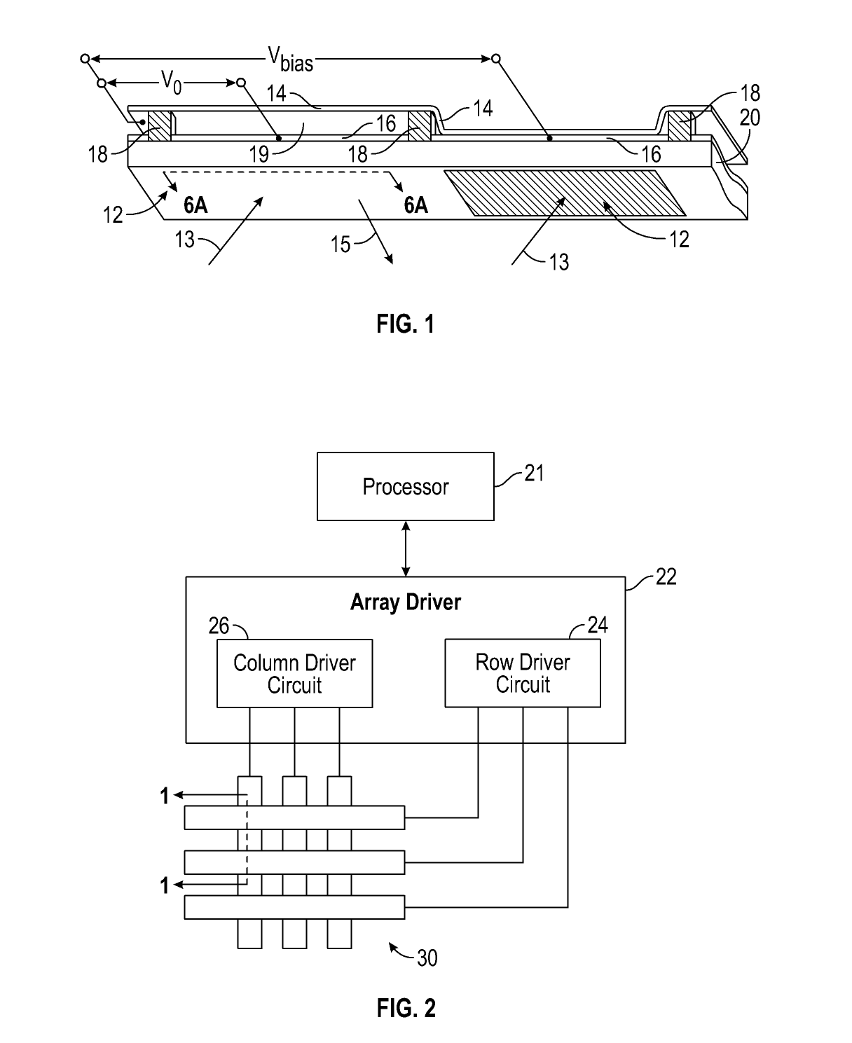

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, for example, to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (such as portions of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

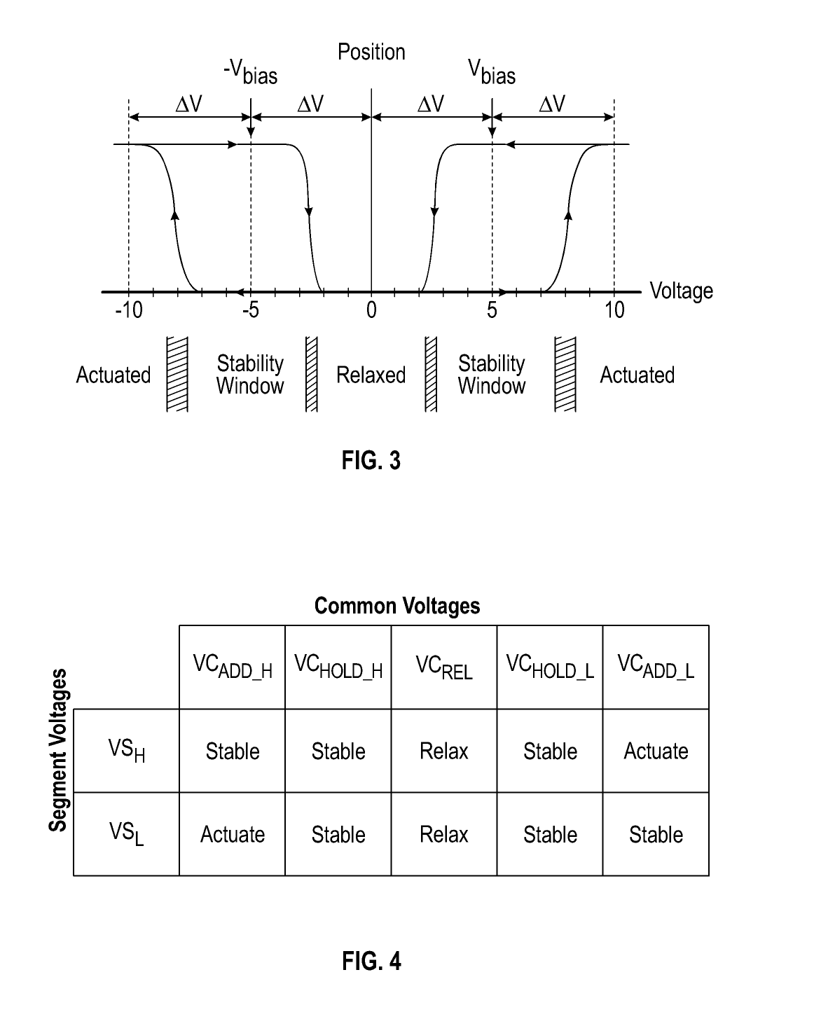

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

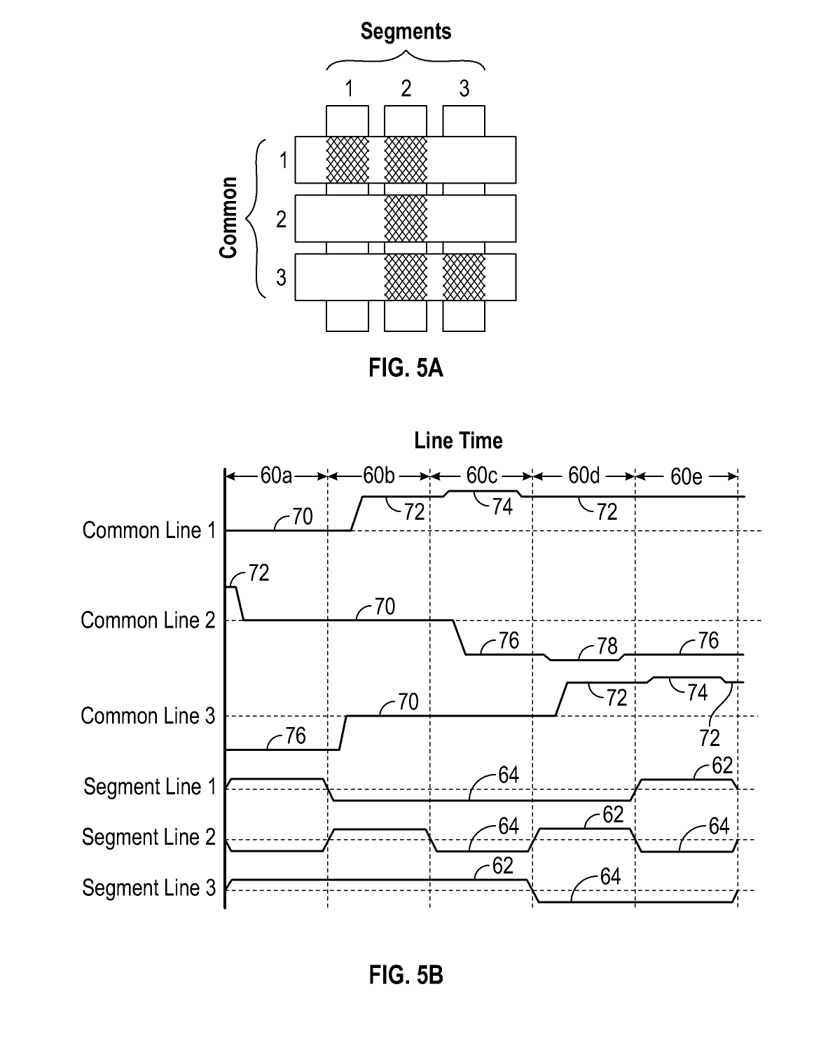

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

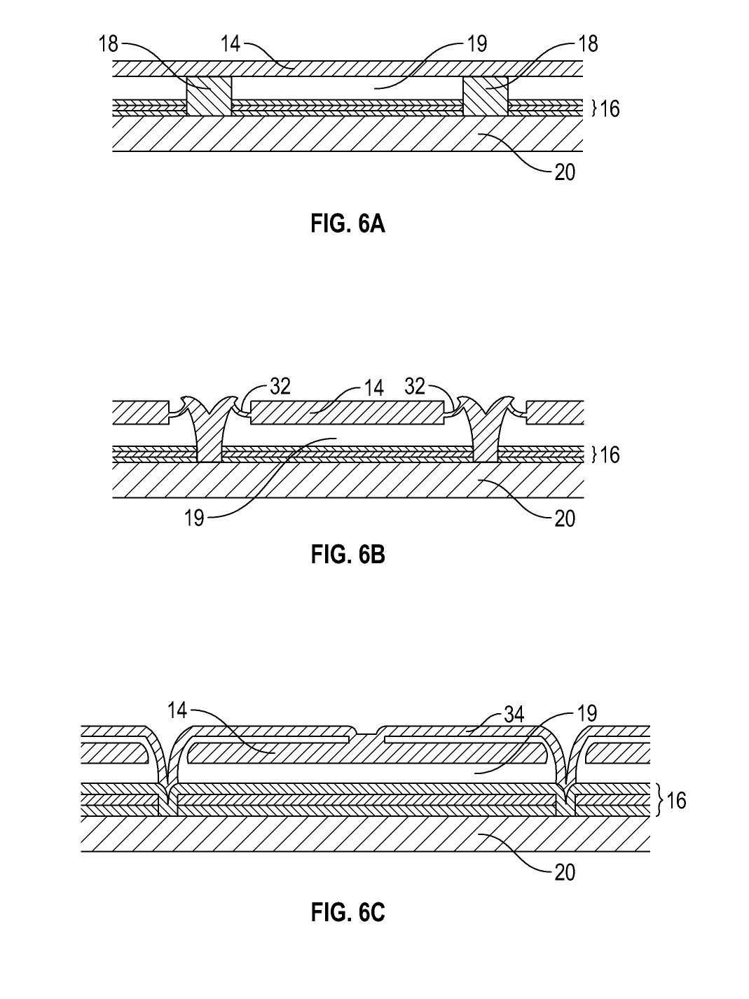

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

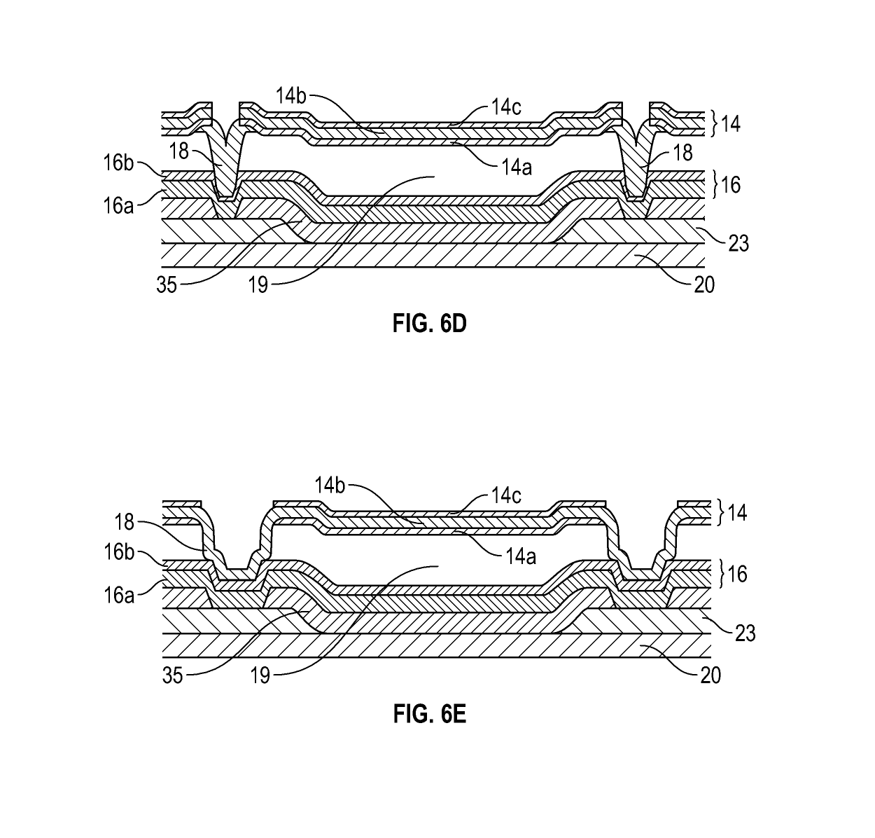

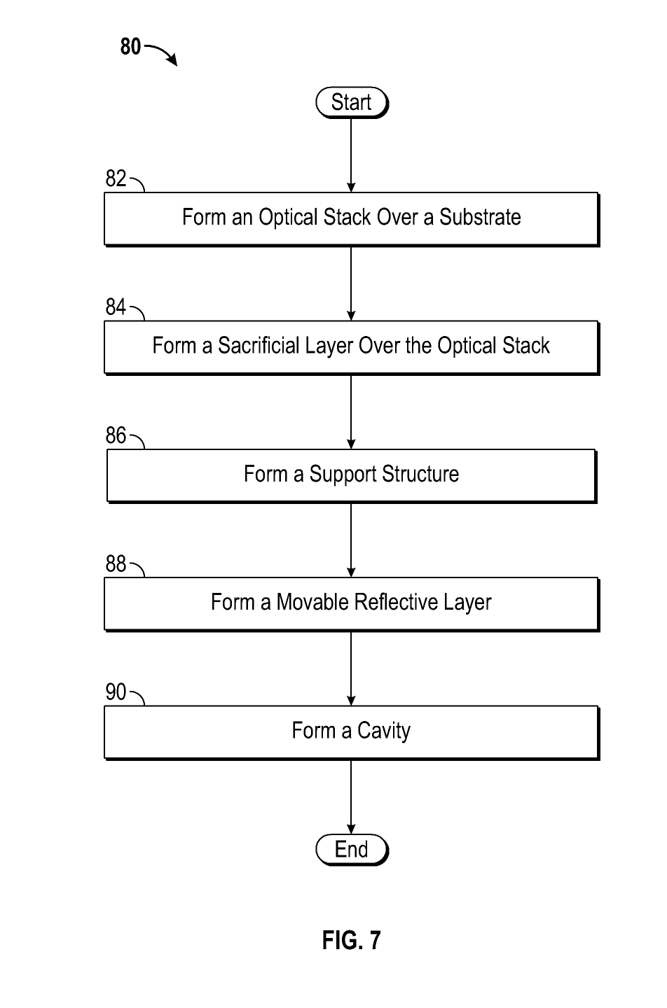

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, in this example, the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

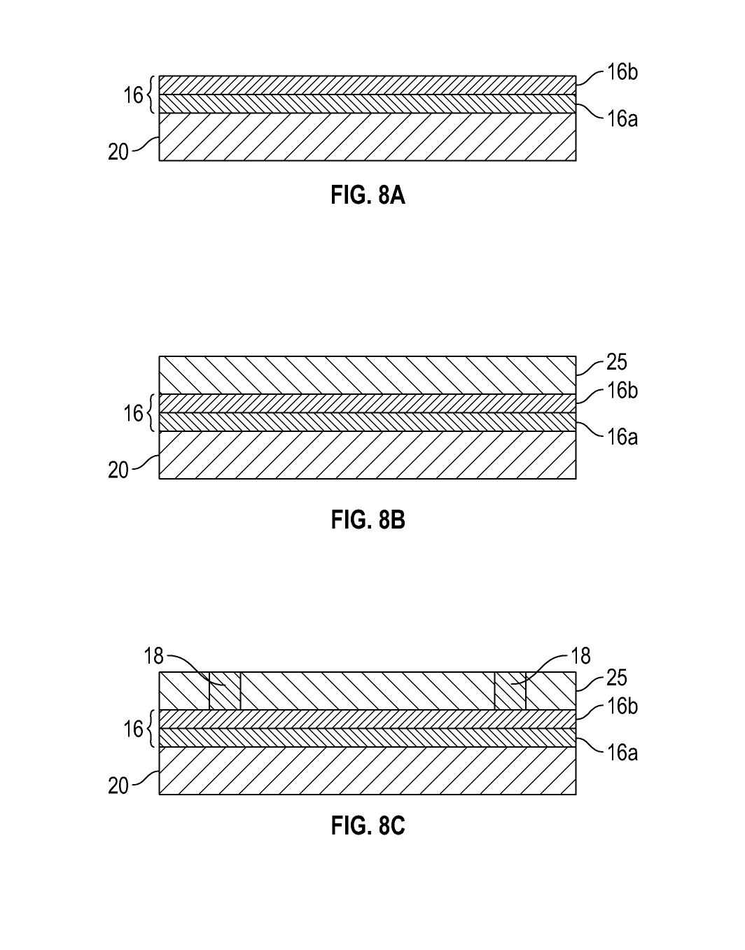

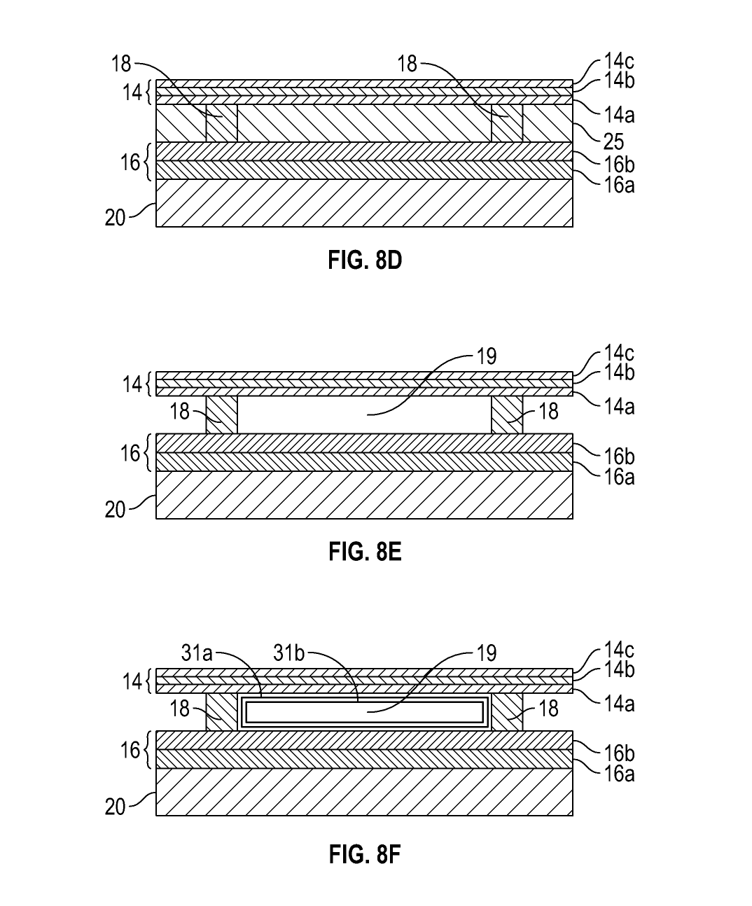

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In this example, the movable electrode and the mechanical layer are one and the same. In FIG. 6B, the movable reflective layer 14 of each IMOD is generally square or rectangular in shape and attached to supports 18 at or near the corners, on tethers 32. The mechanical layer and the movable electrode can also be one and the same in this example. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as supports or support posts 18. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another. The deformable layer 34 can also be referred to as a mechanical layer. Either the deformable layer 34 or the reflective layer 14 could be considered movable layers.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiOₓN_{y}) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under support posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an optical cavity layer, and an Al alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the Al alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes or conductor(s) in the optical stack 16 (such as the absorber layer 16a) from the conductive layers in the black mask 23.

FIG. 6E shows another example of an IMOD, where the movable reflective layer 14 is self supporting. In contrast with FIG. 6D, the implementation of FIG. 6E does not include separately formed support posts. Instead, the movable reflective layer 14 contacts the underlying optical stack 16 at multiple locations to create integrated supports 18, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In the examples of FIGS. 6D and 6E, the entire movable reflective layer 14 or any one or a subset of its sub-layers 14a, 14b and 14c could be considered a mechanical layer or a movable layer. In some implementations, the optical absorber 16a is an order of magnitude (ten times or more) thinner than the movable reflective layer 14. In some implementations, optical absorber 16a is thinner than reflective sub-layer 14a. In some implementations, the optical absorber 16a can serve as a stationary electrode and/or as a partially reflective layer.

In implementations such as those shown in FIGS. 6A-6E, the IMODs function as direct-view devices, in which images are viewed from the front side of the transparent substrate 20, i.e., the side opposite to that upon which the modulator is formed. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

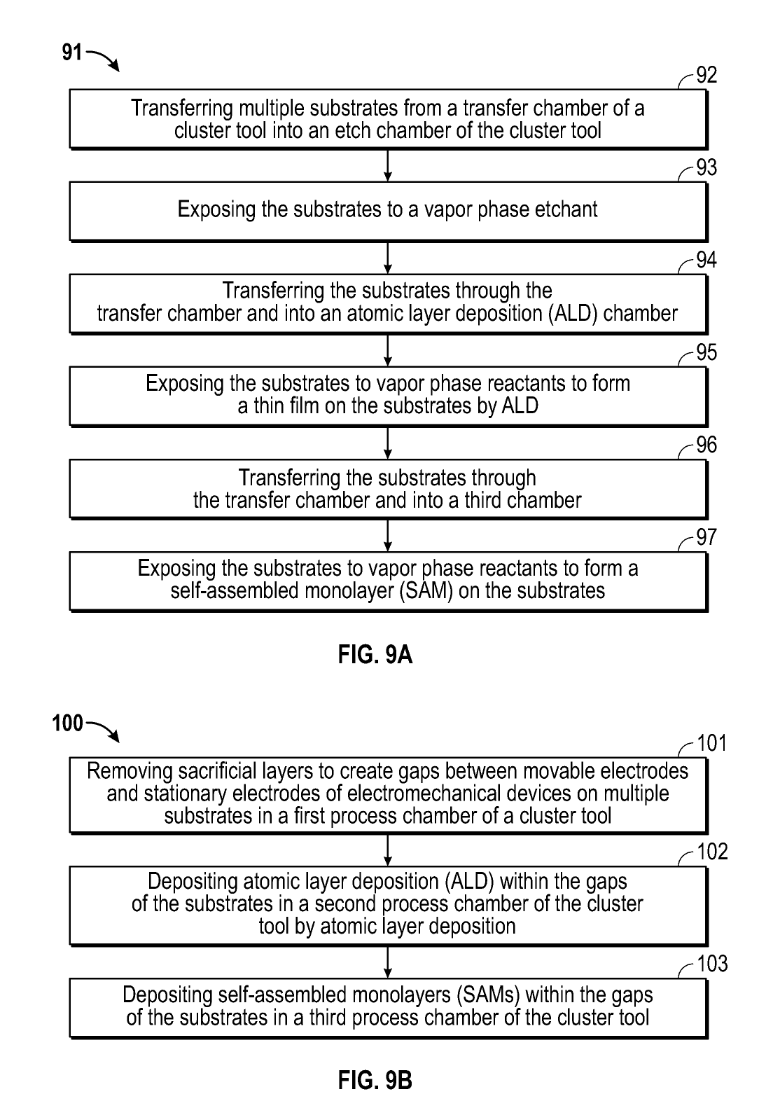

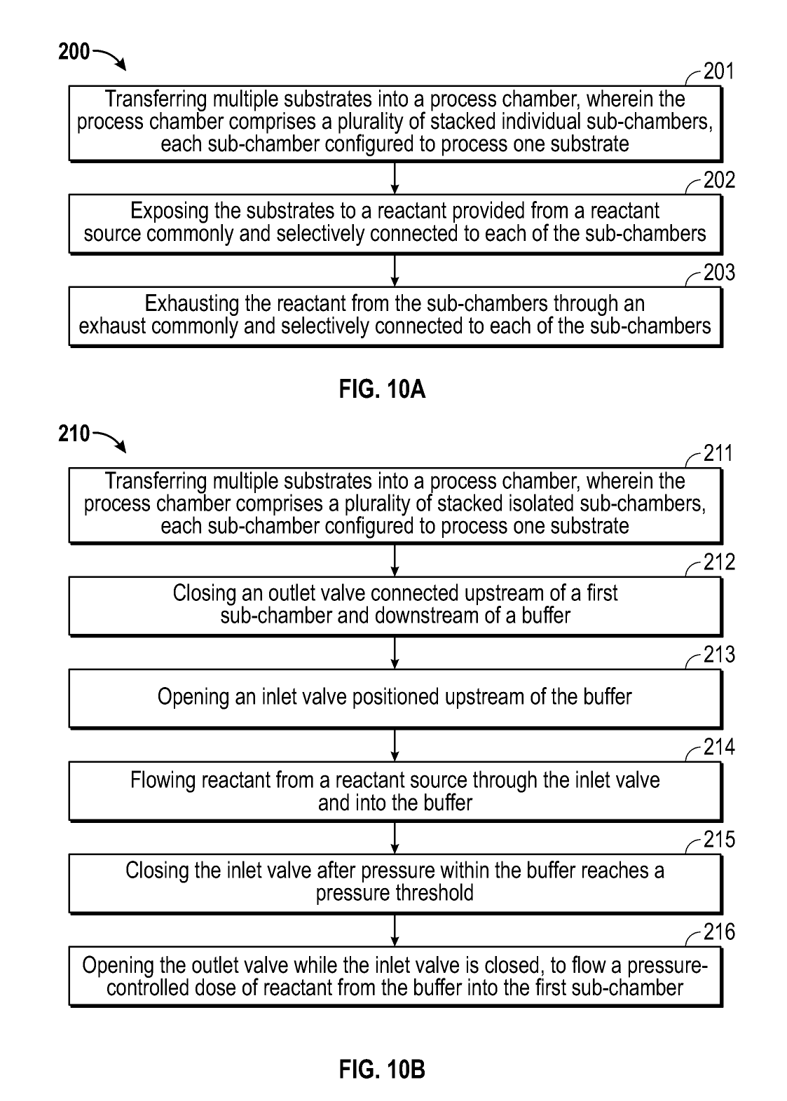

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6A-6E. The manufacture of an electromechanical systems device can also include other blocks not shown in FIG. 7. With reference to FIGS. 1, 6A-6E, and 7, the process 80 begins at block 82 with the formation of the optical stack 16 over the substrate 20. The optical stack 16 includes a lower stationary electrode. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. In non-optical implementations, a stationary electrode can be formed without regard for optical properties. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (such as one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators illustrated in FIGS. 1 and 6A-6E. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material, such as molybdenum (Mo) or amorphous silicon (a-Si), in a thickness selected to provide, after subsequent removal, a gap or cavity 19 (see also FIGS. 1, 6A-6E, and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18 as, illustrated in FIGS. 1, 6A, 6D, 6E and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIGS. 1, 6A-6E, and 8D. The movable reflective layer 14 may be formed by employing one or more deposition processes including, for example, reflective layer (such as Al, Al alloy, or other reflective layer) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b and 14c as shown in FIG. 8D. In some implementations, one or more of the sub-layers, such as sub-layers 14a and 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6A-6E, and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD, and the sacrificial material removal at block 90 may be referred to as a “release etch.”

As shown in FIG. 8F, after release etching defines the cavity, at least the reflective layer 14a and top of the optical stack 16, and in the illustrated implementation all interior surfaces of the cavity 19, can be coated with an antistiction layer. The illustrated antistiction layer includes an ALD layer 31a, formed by atomic layer deposition (ALD), and a self-assembled monolayer (SAM) as described below. It will be understood that antistiction properties can be obtained with one or both of the ALD layer and the SAM. For implementations in which both are employed, the ALD layer 31a can serve as a seed layer for forming the SAM thereover.

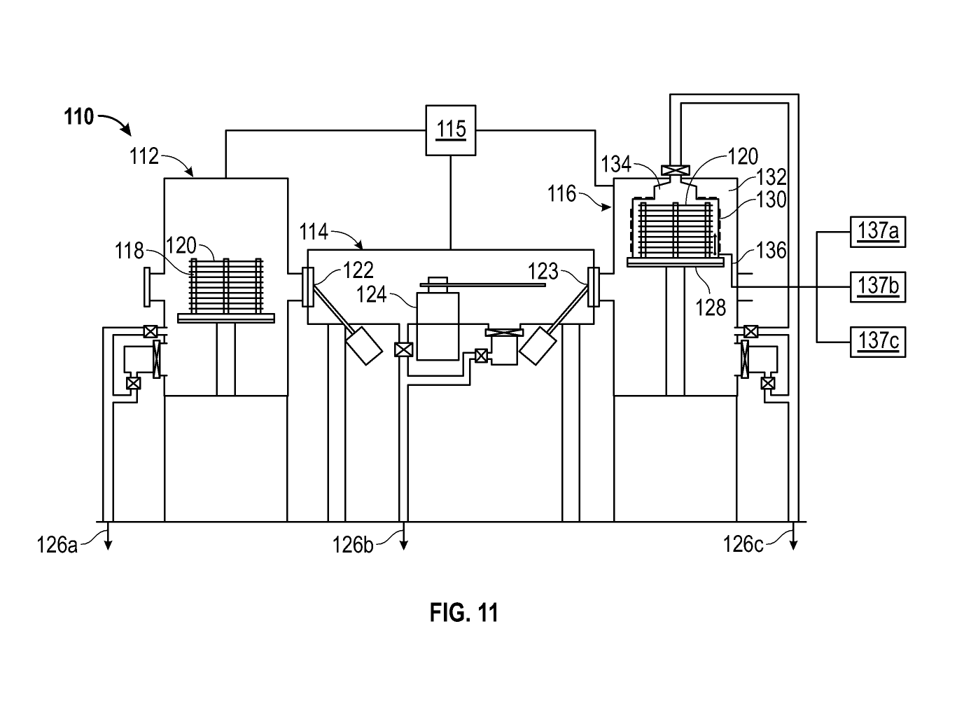

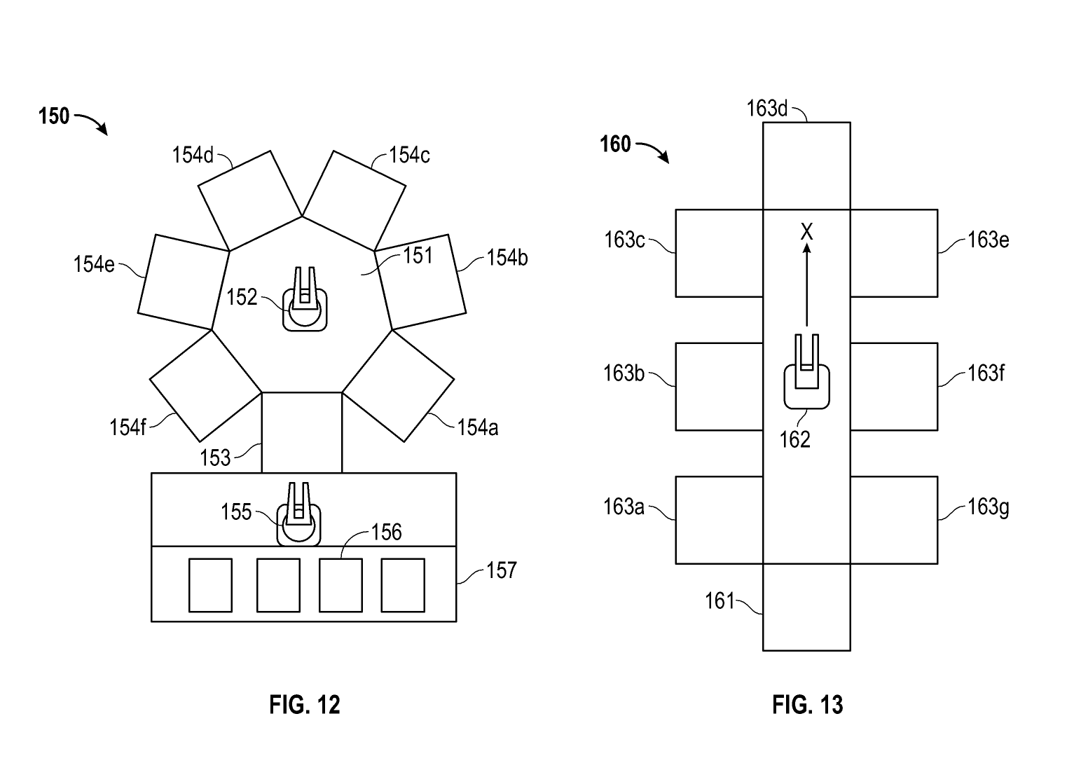

FIG. 9A shows an example of a flow diagram illustrating a method 91 for processing multiple substrates. In some implementations the method 91 includes at block 92 transferring multiple substrates from a transfer chamber of a cluster tool into an etch chamber of the cluster tool. At block 93, the substrates are exposed to a vapor phase etchant. In some implementations, a sacrificial layer is etched in the etch chamber to leave a cavity between electrodes of an electromechanical systems device. At block 94, the substrates are transferred from the etch chamber through the transfer chamber and into an atomic layer deposition (ALD) chamber. At block 95, the substrates are exposed to vapor phase reactants to form a thin film on the substrates by ALD. At block 96, the substrates are transferred from the ALD chamber through the transfer chamber and into a third chamber. At block 97, the substrates are exposed to vapor phase reactants to form a self-assembled monolayer (SAM) on the substrates. In some implementations the method includes blocks 92, 93, 94, and 95 to etch the substrates and form a thin film by ALD on the substrates in the cluster tool, without a subsequent SAM deposition. In some implementations the method includes blocks 92, 93, 96, and 97 to etch the substrates and form a SAM on the substrates in the cluster tool, without an intervening ALD process.

As noted above, FIG. 8F shows an example of an IMOD having the cavity 19 with the ALD layer 31a and the SAM layer 31b formed within the cavity 19. The vapor phase deposition reactants can reach the interior surfaces of the cavity 19 by the same paths that the release etch vapors follow, such as etch holes (not shown) in the reflective movable layer 14, and laterally between supports 18. Although not illustrated, one having ordinary skill in the art will recognize that the ALD and/or SAM depositions can also leave ALD and SAM layers on outer surfaces of the device, such as the upper surface of the conductive layer 14c.

FIG. 9B shows an example of a flow diagram illustrating a method for processing multiple substrates. In some implementations a method 100 for forming an electromechanical systems device is provided. The method 100 includes at block 101 removing sacrificial layers to create gaps between movable electrodes and stationary electrodes of electromechanical devices on multiple substrates in a first process chamber of a cluster tool. At block 102, atomic layer deposition (ALD) layers can be deposited within the gaps of the substrates in a second process chamber of the cluster tool by ALD. At block 103, self-assembled monolayers (SAMs) can be deposited within the gaps of the substrates in a third process chamber of the cluster tool 73. In some implementations, blocks 101 and 102 are performed to form an ALD layer within the gaps and no SAM is formed, such that the ALD layer is exposed to the cavity on both electrode surfaces. In some implementations, blocks 101 and 103 are performed to form an SAM layer within the gaps without an underlying ALD layer. In some implementations the SAM layer can be formed on an aluminum oxide etch stop layer within the cavity of the substrate.

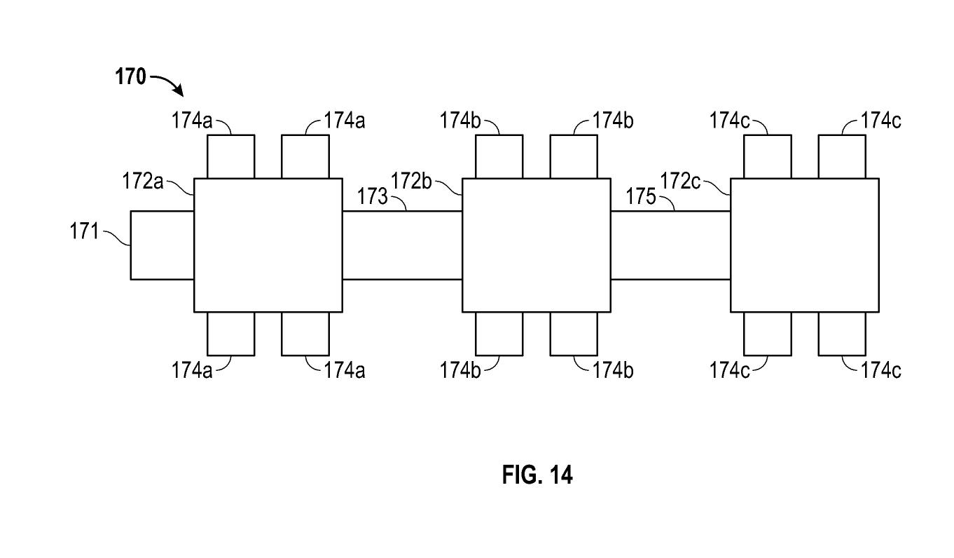

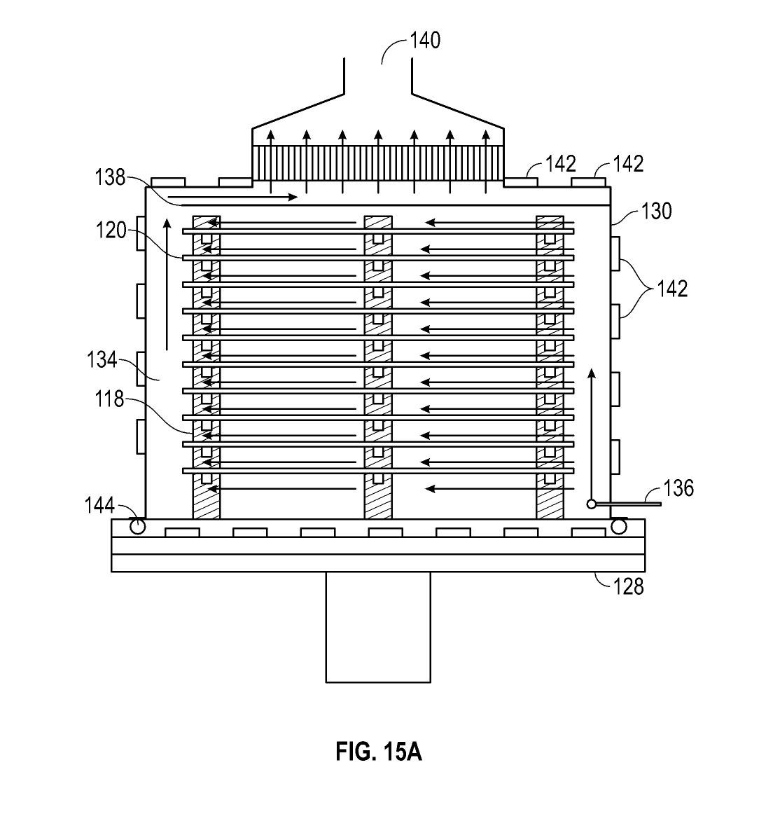

FIG. 10A shows an example of a flow diagram illustrating a method of processing substrates. In some implementations, a method 200 for processing substrates is provided. The method includes at block 201 transferring multiple substrates into a process chamber, wherein the process chamber comprises a plurality of stacked individual subchambers, each subchamber configured to process one substrate. At block 202, the substrates can be exposed to a reactant provided from a reactant source commonly and selectively connected to each of the subchambers. At block 203, the reactant can be exhausted from the subchambers through an exhaust commonly and selectively connected to each of the subchambers.

FIG. 10B shows an example of a flow diagram illustrating a method of processing substrates. In some implementations, a method 210 for processing substrates is provided. The method includes at block 211 transferring multiple substrates into a process chamber, wherein the process chamber comprises a plurality of stacked individual subchambers, each subchamber configured to process one substrate. At block 212, an outlet valve connected upstream of one of the subchambers and downstream of a buffer can be closed. At block 213, an inlet valve positioned upstream of the buffer can be opened. At block 214, reactant can be flowed from a reactant source through the inlet valve and into the buffer. At block 215, the inlet valve can be closed after pressure within the buffer reaches a pressure threshold. At block 216, the outlet valve can be opened while the inlet valve is closed, to flow a pressure-controlled dose of reactant from the buffer into the one of the subchambers.

The methods 91, 100, 200 and/or 210 can be implemented to process multiple substrates in any of a number of different ways. In some implementations, multiple substrates can be processed with method 91 and/or 100 in a batch within a process chamber in which the substrates are in open communication with one another and common reactant inlet(s) and exhaust(s). In some implementations, one or more of the process chambers (first, second and third process chambers, or etch, ALD and third chambers) can include an inner chamber and an outer chamber. In some implementations, one or more of the process chambers can include multiple inner chambers, or subchambers within the outer chamber. Each subchamber can be configured to process a single substrate. Processing within the subchambers can be conducted in parallel.

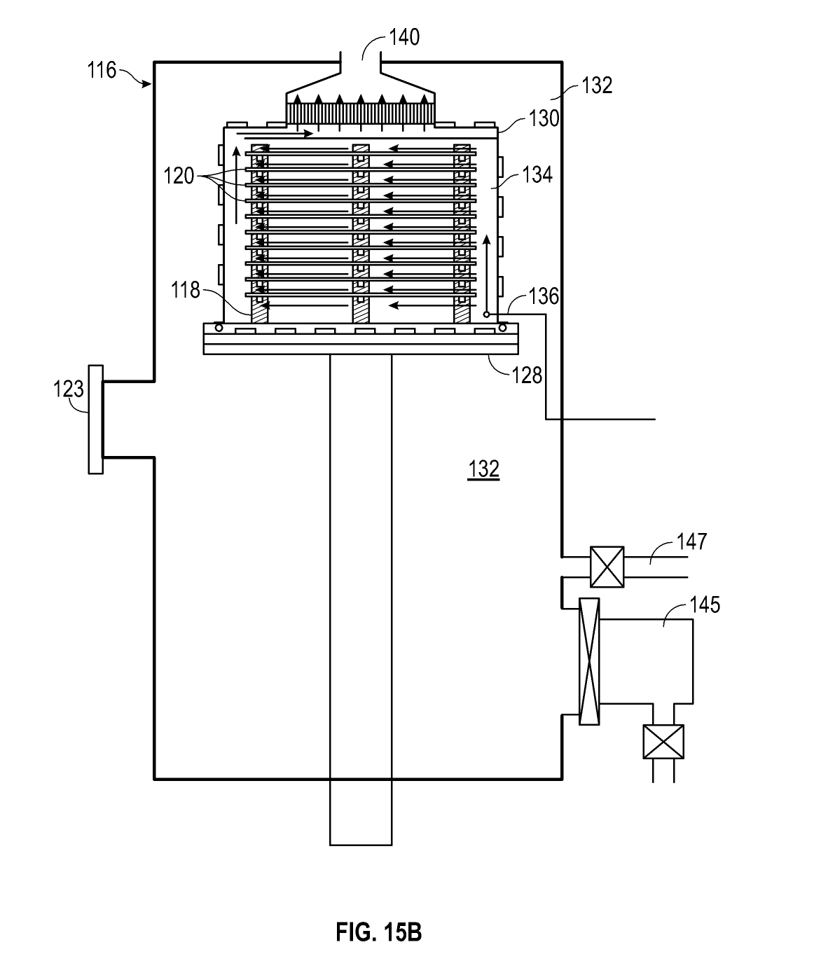

FIG. 11 is a schematic cross section of an example of an apparatus 110 for batch processing. The batch cluster tool 110 includes a load lock chamber 112, a transfer chamber 114, and one or more process chambers 116. The load lock chamber 112 is configured to handle a boat or rack 118 or otherwise configured to handle multiple substrates 120. The load lock chamber 112 can be configured to receive a loaded cassette of substrates from an outside loading platform (not shown). The substrates 120 can be transferred from the load lock chamber 112 through a door 122 into the transfer chamber 114 using a robot 124. The transfer chamber 114 is in selective communication with the load lock chamber 112 and one or more process chambers 116. The transfer chamber 114 is in selective communication with the process chamber 116 when a door 123, such as a gate valve, is open. The transfer chamber 114 is in selective communication with the load lock chamber 112 when the door 122, such as a gate valve, is open. The robot 124 is configured to transfer one or more substrates 120 among the transfer chamber 114, the load lock chamber 112 and the one or more process chambers 116. The process chamber 116 is configured with a platform 128 configured to hold a boat 118 with multiple substrates 120. The platform 128 is provided with an indexing elevator mechanism, capable of moving up and down to facilitate the transfer of substrates 120 through the door 123, and the load lock chamber 112 can be provided with a similar indexing mechanism. The process chamber 116 has an internal volume 132. The platform 128 is configured to engage with a reactor shell 130 to form a reaction space volume 134 within the process chamber 116. The reactions space volume 134 can be considered an inner chamber within the outer process chamber 116. The reaction space volume 134 is separate from the internal volume 132 of the process chamber 116 when the platform 128 is engaged with the reactor shell 130 and can form an airtight seal. The reaction space volume 134 is in fluid communication through one or more reactant inlet(s) 136 with one or more reactant sources 137a, 137b, and 137c. The load lock chamber 112, transfer chamber 114, and process chamber 116 are in fluid communication with exhaust lines 126a, 126b, and 126c, respectively, which can be connected to one or more vacuum pump(s) to reduce the pressure in the load lock chamber 112, transfer chamber 114, and process chamber 116. The process chamber 116 and reaction space volume 134 can be configured to perform various processes.

The batch cluster tool 110 can be controlled by a controller 115 configured to control the various functions of the load lock chamber 112, the transfer chamber 114, and the process chamber 116, to perform the desired wafer handling, reactant supply, process pressures, and processes. In some implementations the controller 115 includes a memory and a processor and is configured or programmed to perform the processes illustrated in FIGS. 9 and 10. In some implementations the controller 115 is configured to control the vacuum pumps connected to 126a, 126b, and 126c, respectively. In some implementations, the controller 115 is a master controller that controls subcontrollers for individual chambers, devices or groups of devices in the cluster tool 110.

In some implementations the reactant sources 137a, 137b, and 137c are gas delivery systems or subsystems configured to contain, meter and deliver in the vapor phase reactants for the release etch, ALD layer deposition, and SAM deposition.

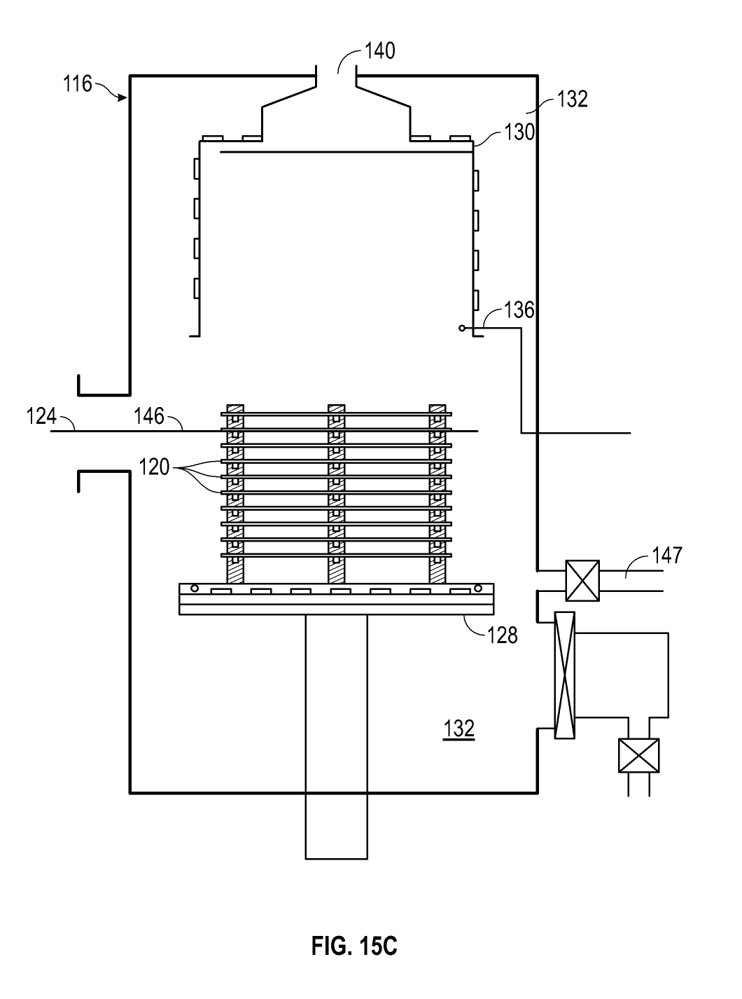

FIG. 12 is a schematic plan view of one example of an apparatus for batch processing. FIG. 12 is a schematic plan view of a batch cluster tool 150. The batch cluster tool 150 includes a transfer chamber 151, a transfer robot 152, a load lock chamber 153, and multiple processing chambers 154a-154f (six shown). FIG. 12 also illustrates a second transfer robot 155 adjacent to a cassette station 157 including multiple cassettes 156, each configured to hold multiple substrates. The second transfer robot 155 can transfer individual substrates or an entire cassette of substrates into or out of the cassette station. The transfer robot 152 is configured to rotate and extend to reach into the internal spaces of the load lock chamber 153 and process chambers 154a-154f to move one or more substrates into and out of the load lock chamber 153 and process chambers 154a-154f. The process chambers 154a-154f can be configured to carry out one or more processes on the substrates. For example, each of the process chambers can be configured to carry out one of or all of the release etch, deposition of the ALD layer, and deposition of the SAM. Tables 1 and 2 below illustrate examples of various configurations for the different process chambers 154a-154f, with an X indicating capability (configuration and plumbing) of performing the indicated process.

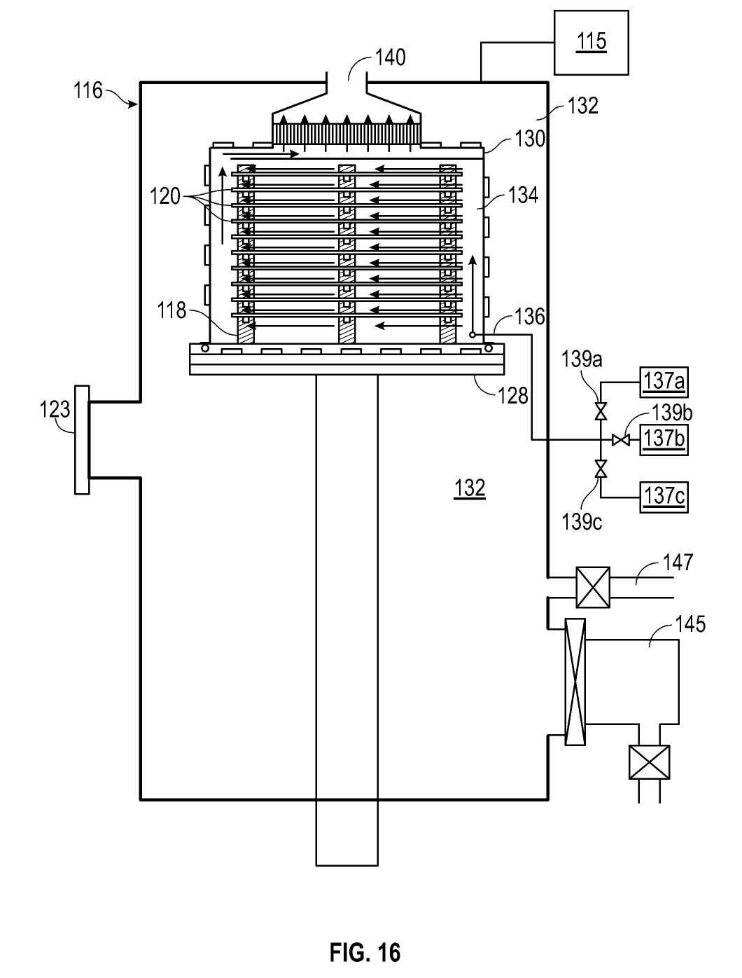

FIG. 13 is a schematic plan view of another example of an apparatus for batch processing. FIG. 13 illustrates a batch cluster tool 160 configured differently from FIG. 12. The batch cluster tool 160 includes a load lock chamber 161, a transfer robot 162, and multiple process chambers 163a-163g (seven shown). The transfer robot 162 is configured to move horizontally in the direction between the load lock chamber 161 and process chamber 163d. The transfer robot 162 is also configured to rotate and extend to reach into the internal spaces of the load lock chamber 161 and process chambers 163a-163g to move one or more substrates individually and sequentially one at a time into and out of the load lock chamber 161 and process chambers 163a-163g. In some implementations the robot could have multiple paddles or end effectors to transfer multiple substrates at a time. In some implementations the robot could transfer racks or boats among chambers. The process chambers 163a-163g can be configured to carry out one or more processes on the substrates. For example, each of the process chambers can be configured to carry out one of or all of the release etch, deposition of the ALD layer, and deposition of the SAM. Tables 1 and 2 illustrate examples of various configurations for the different process chambers 163a-163g, with an X indicating capability (configuration and plumbing) of performing the indicated process.

TABLE 1

| Process Chamber | Release/Etch | ALD | SAM |
|---|---|---|---|
| 154a, 163a | X | X | X |
| 154b, 163b | X | X | X |
| 154c, 163c | X | X | X |
| 154d, 163d | X | X | X |
| 154e, 163e | X | X | X |
| 154f, 163f | X | X | X |
| 163g | X | X | X |

TABLE 2

| Process Chamber | Release/Etch | ALD | SAM |
|---|---|---|---|
| 154a, 163a | X | | |
| 154b, 163b | | X | |
| 154c, 163c | | | X |
| 154d, 163d | X | | |
| 154e, 163e | | X | |
| 154f, 163f | | | X |
| 163g | X | X | X |

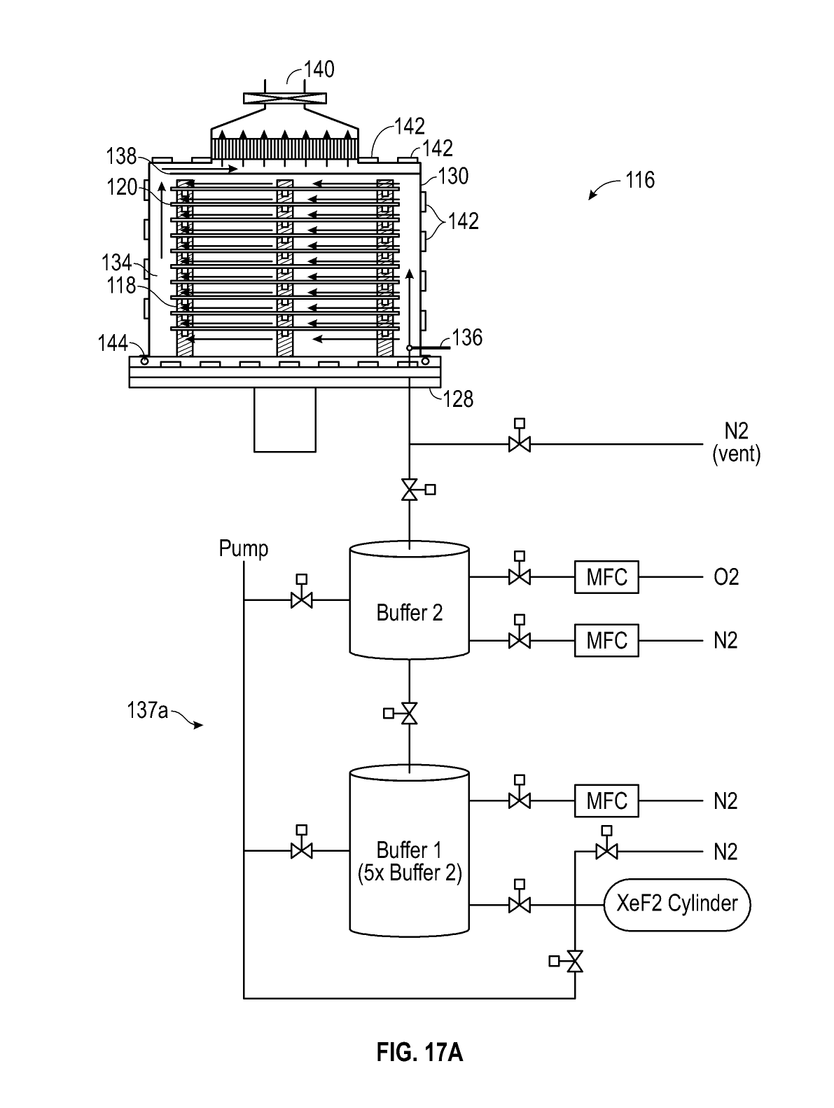

FIG. 14 is a schematic plan view of another example of an apparatus for batch processing. The batch cluster tool 170 includes a load lock chamber 171 and multiple process chambers 174a, 174b and 174c. The batch cluster tool includes transfer chambers 172a, 172b and 172c. The batch cluster tool includes transfer corridors 173 and 175. Substrates can be transferred from the load lock chamber 171 into the first transfer chamber 172a. Substrates can be transferred from the first transfer chamber 172a into the first process chambers 174a. Multiple substrates can be processed simultaneously in each of the first process chambers 174a. After processing multiple substrates in parallel or in staggered fashion, the substrates can be transferred from the first process chambers 174a to the first transfer chamber 172a. Multiple substrates can be transferred from the first transfer chamber 172a through the first transfer corridor 173 to the second transfer chamber 172b. Multiple substrates can be transferred from the second transfer chamber 172b to the second process chambers 174b for processing. After processing multiple substrates in parallel or in staggered fashion, the substrates can be transferred from the second process chambers 174b to the second transfer chamber 172b. Multiple substrates can be transferred from the second transfer chamber 172b through the second transfer corridor 175 to the third transfer chamber 172c. Multiple substrates can be transferred from the third transfer chamber 172c to the third process chambers 174c for processing. In some implementations each of the transfer chambers 172a, 172b, 172c, 173 and 175 can have a transfer robot (not shown). The process chambers 174a, 174b and 174c can be configured to carry out one or more processes on the substrates. For example, each of the first process chambers 174a can be configured to carry out the release etch, each of the second process chambers 174b can be configured to carry out deposition of the ALD layer, and each of the third process chambers 174c can be configured to conduct deposition of the SAM. In some implementations the transfer corridors 173 and 175 are maintained at a lower pressure than the transfer chambers 172a, 172b and 172c to decrease the diffusion of process gases between the different processes and cross-contamination. Staggering processing within the multiple process chambers 172a, 172b or 172c of each stage can be more efficient than parallel processing to stagger the load on the transfer robots.

The process chambers in the batch cluster tool can be configured to perform different deposition processes. For example, the batch cluster tool can have process chambers configured for the etch/release, configured for the formation of an ALD layer, and configured for the formation of a SAM layer. The cluster tool can have one or more controller(s) programmed for performing each of the release, formation of an ALD layer, and formation of a SAM layer in the various process chambers. For example, a batch cluster tool with six processing chambers can include two process chambers configured for each of the etch, ALD layer formation, and SAM layer formation.

After the etch and release the processed substrates are delicate and sensitive to contamination. In some implementations cross contamination of process gases between the different processes is minimized. In some implementations the cluster tool provides minimal movement of process gases between different processes after the release. In some implementations relative pressures are chosen for the transfer chamber, process chambers, and reaction spaces to minimize cross-contamination among the different chemicals for the release, ALD process, and SAM formation.

In some implementations, the different process chambers can be arranged to minimize the transfer time of the substrates between the different processing chambers.

In some implementations the reaction spaces and/or process chambers are purged after processing the substrates and before opening the door between the process chamber and transfer chamber to minimize contamination between the different process chambers and process gases.

In some implementations transferring the substrate can include batch transfer of multiple substrates or an entire rack or boat containing multiple substrates. In some implementations transferring the substrate can include sequentially transferring individual substrates between the transfer chamber and the processing chambers. In some implementations the robot could have multiple paddles or end effectors to transfer multiple substrates at a time. In some implementations the robot could transfer racks or boats among chambers.

In some implementations a robot is used to transfer the substrates or racks between chambers. In some implementations the transfer robot can rotate and extend horizontally to move substrates or racks (such as boats) into or out of a process chamber or load lock chamber.

Different types of substrates can be transferred by the robot and accommodated by the racks. In some implementations rectangular substrates are used. In some implementations circular substrates are used. In some implementations glass substrates are used. In some implementations glass substrates for displays are used. In some implementations glass substrates for EMS displays are used. In some implementations glass substrates are used for IMOD displays. In some implementations the cluster tool, transfer robot, process chambers, subchambers described herein, or components thereof, such as lift pin assemblies, are configured to handle standard large format rectangular substrates, including G1 (˜300 mm×350 mm); G2 (˜370 mm×470 mm); G3 (˜550 mm×650 mm); G4 (˜730 mm×920 mm); G5 (˜1100 mm×1250 mm); G6 (˜1500 mm×1850 mm); G7 (˜1950 mm×2200 mm); G8 (˜2200 mm×2400 mm); G10 (˜2880 mm×3130 mm); In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. In some implementations, the substrate may be or include silicon, or other materials used in IC manufacturing.

In some implementations the process chambers are configured to process five or more substrates at the same time. In some implementations the process chambers are configured to process from about 5 substrates to about 25 substrates. In some implementations more than 25 substrates can be processed simultaneously in the process chambers.

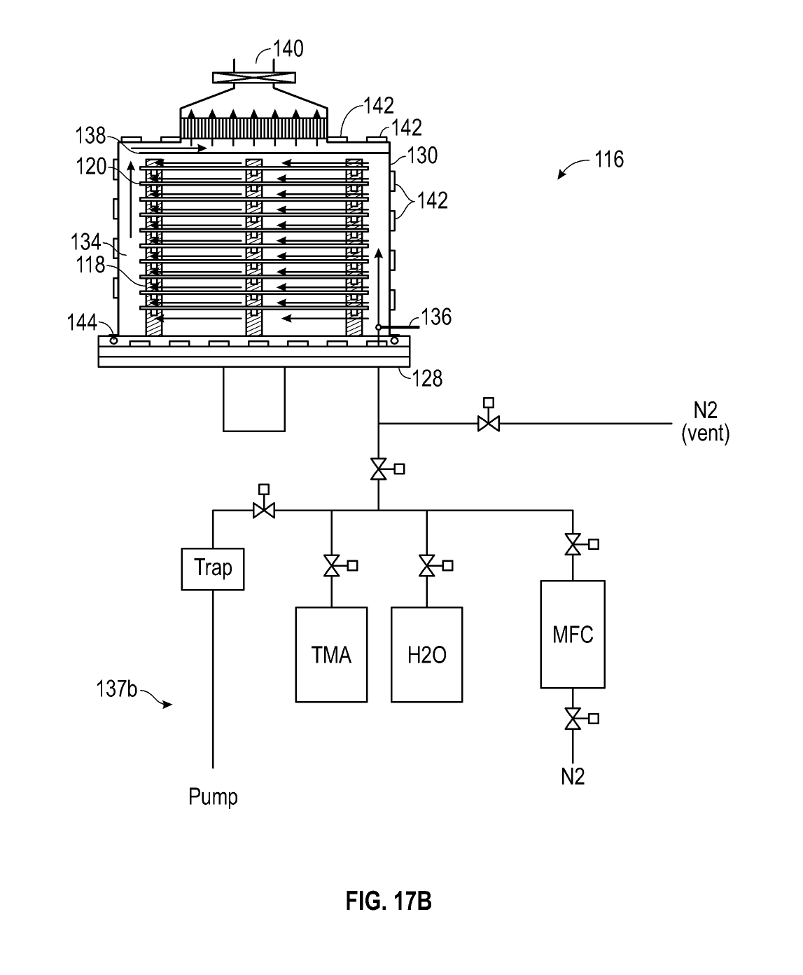

FIGS. 15A-15C show schematic cross sections of a batch process chamber useful for batch cluster tools like those of FIGS. 11-14. FIG. 15A shows a cross section of a portion of the process chamber including the reactor shell 130 and the platform 128. The reactor shell 130 and the platform, when closed, define the reaction space volume 134. Within the reaction space volume 134 is a boat 118 holding multiple substrates 120. Process vapors can be introduced to the reaction space volume 134 through one or more inlet line(s) 136. The boat 118, substrates 120, and line(s) 136 are arranged such that the process vapors flow parallel across each of the substrates 120 before exiting the reaction space volume 134 through an exhaust 140. The reactor shell 130 also has a baffle 138 to guide the flow of vapor process gases across the substrates 120. The reactor shell 130 can also have heaters 142 that can be used to heat the substrates 120 within the reaction space volume 134. The platform 128 is configured to engage with the reactor shell 130 with a gasket 144 to form the reaction space volume 134. The platform 128 can move down to lower position(s) for loading substrates 120 through the door 123 (FIG. 11). The platform 128 can move up to engage with the shell 130 after the substrates 120 are loaded to form a seal. After the platform 128 is engaged with the shell 130, process gases can be used to carry out desired processes on the substrates 120 followed by purging the reaction space 134. The substrates 120 can be removed after lowering the platform 128. In other implementations the reactor shell 130 can move, or the seal can be established by any combination of relative movement between the platform 128 and the shell 130.

FIG. 15B is a schematic cross section of the process chamber 116 with the reaction shell 130 sealed from the internal volume 132 of the process chamber 116. The exhaust 140 from the shell can be used to remove contaminants and decrease the pressure in the reaction space volume 134. In some implementations process chamber exhausts 145 and 147 can be connected to different types of vacuum pumps. For example, the process chamber exhaust 147 can be connected to a roughing pump for achieving pressures between about 10 mTorr and atmospheric pressures. The exhaust 145 can be connected to a turbo molecular pump (TMP) for achieving pressures below 100 mTorr, such as 10⁻⁶ or 10⁻⁷ Torr. One or more isolation valves can be configured to selectively control flow to the exhausts 145, 147 from the internal volume 132 of the process chamber 116. In some implementations, an additional gate valve can be positioned between the isolation valve (e.g., of exhaust 145) and the internal volume 132 of the process chamber 116. In some implementations, the exhausts 145, 147 can be combined in an integrated exhaust that includes both a roughing pump and TMP.

FIG. 15C is a schematic cross section of the process chamber 116 with the platform 128 in a lowered position such that it is not engaged with the reactor shell 130. The door 123 (FIG. 11) between the transfer chamber 114 and process chamber 116 is shown as open. An end effector 146 of the transfer robot 124 (FIG. 11) is extended into the process chamber 116 to remove or load a substrate 120. As noted above, in some implementations the robot could have multiple paddles or end effectors to transfer multiple substrates at a time. In some implementations the robot could transfer racks or boats among chambers.

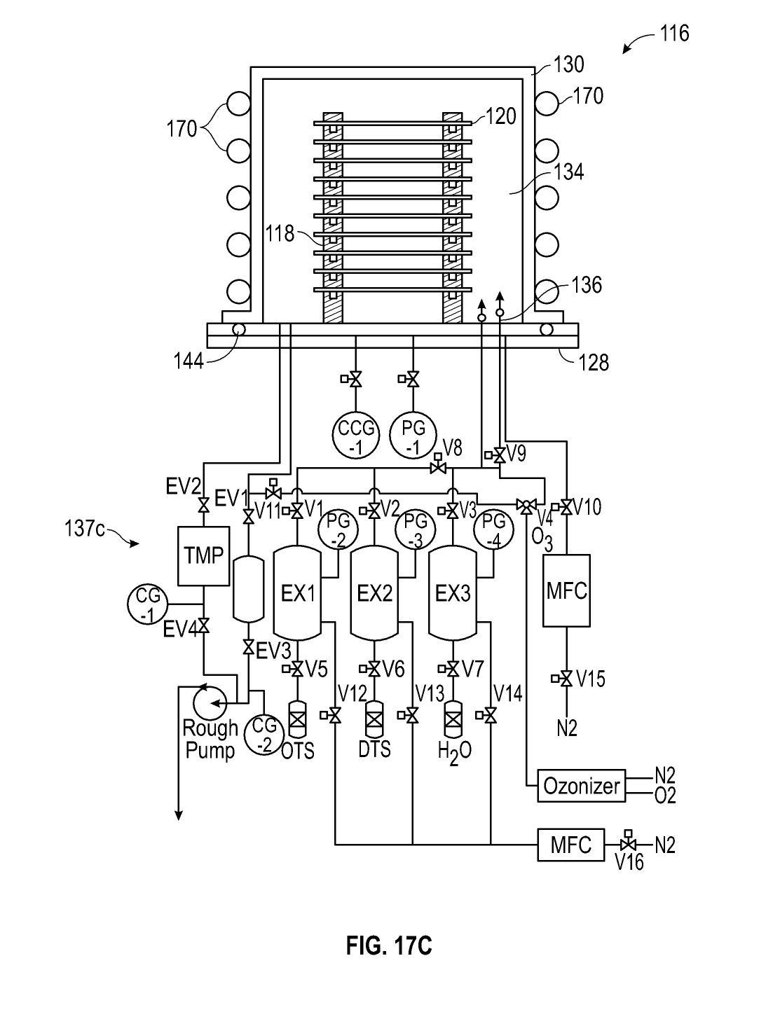

FIG. 16 shows a schematic cross section of an example of a batch process chamber, having connections to three different gas delivery systems configured for etching, atomic layer deposition (ALD) and self-assembled monolayer (SAM) deposition. In some implementations components of the process chamber 116 are connected to the controller 115 and reactants sources 137a, 137b, and 137c. The controller 115 can be configured to control the pressure and temperature in the process chamber 116 and reaction space volume 134 through exhausts 140, 145 and 147. The controller 115 can be configured to control valves 139a, 139b and 139c to supply process gases from the reactant sources 137a, 137b and 137c, respectively. The reactants sources 137a, 137b and 137c can each be gas delivery systems or subsystems configured to contain, meter and deliver reactant vapors used for the release etch, ALD layer formation, and SAM layer deposition.

The reactants sources 137a, 137b and 137c can contain reactive process gases and inert gases for purging the reaction space. The process controller 115 can be configured to perform the depositions of the ALD layer and SAM layer. For example, FIG. 8F shows an example of an IMOD having a cavity 19 and ALD layer 31a and SAM layer 31b formed within the cavity 19.

In some implementations the process chambers and reaction spaces can be used to etch a portion of the processed substrate. For example, the etch can be used for the release process. In some implementations a vapor phase etchant is used. In some implementations XeF₂ is vaporized and provided to the reaction space to etch portions of the substrate.

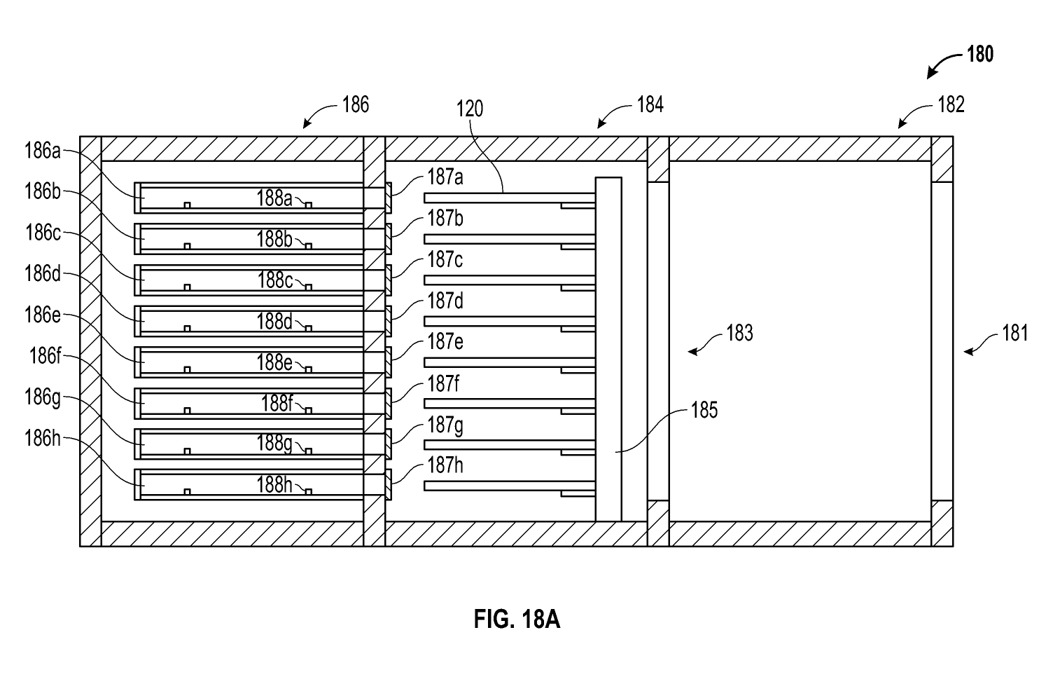

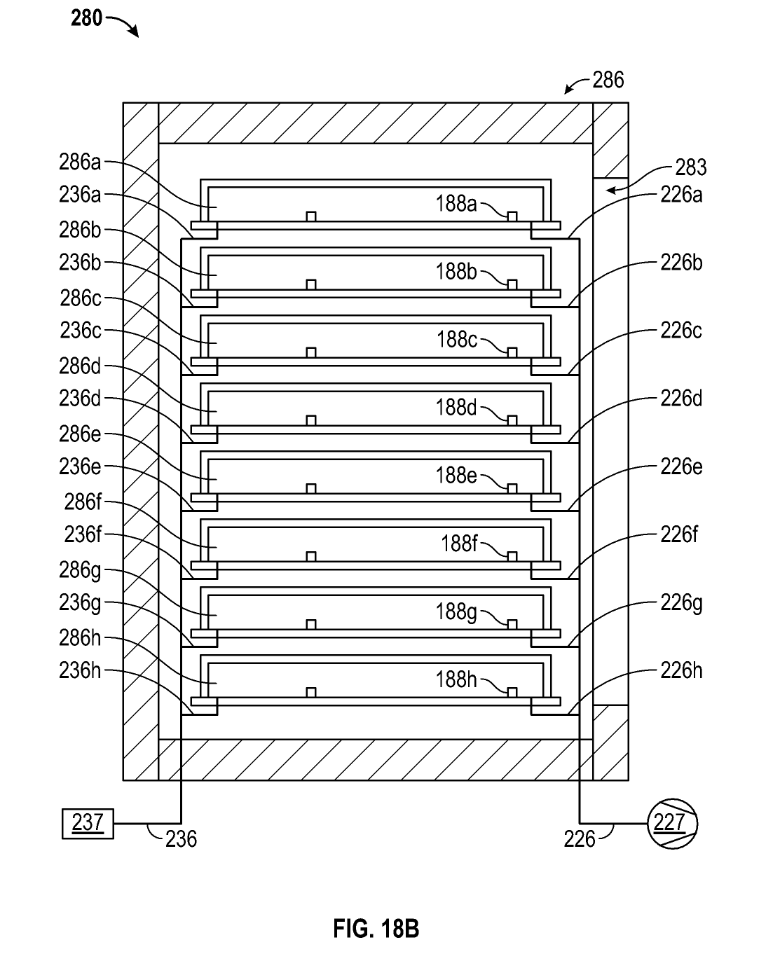

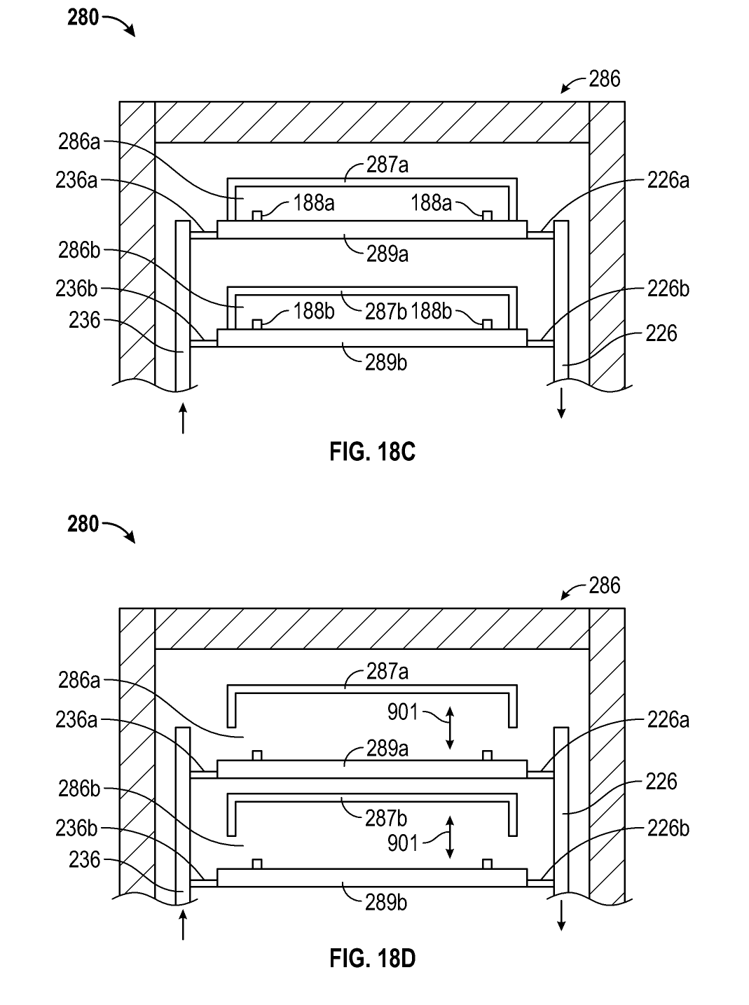

In some implementations the example of a batch process chamber 116 shown in FIG. 16 can be configured to perform the release etch. The reactant source 137a can be a vapor delivery system or subsystem configured to contain, meter and deliver an etchant such as XeF₂ or XeF₂ combined with a buffer to achieve a desired concentration of XeF₂. The reactant source 137a can additionally provide an inert gas, such as nitrogen for purging the reaction space after the release etch is completed. In some implementations the controller 115 is configured to open the valve 139a to supply XeF₂ to the batch substrates to perform the etch release. The controller 115 can also be configured to provide an inert gas to purge the reaction space after etching has proceeded sufficiently long to remove the sacrificial layer and form the cavity between electrodes of the electromechanical system devices. Further details of an example of a gas delivery system that can be used for the reactant source 137a for conducting release etching is illustrated and described with respect to FIG. 17A below.

In some implementations the batch process chamber 116 shown in FIG. 16 can be configured to deposit the ALD layer. The reactant source 137b can be a gas delivery system or subsystem configured to contain an aluminum source vapor such as TMA, an inert or purge gas, and an oxygen source vapor such as water. In some implementations the controller 115 is programmed to open the valve 139b to saturate the batch substrates with adsorbed TMA, followed by purging of the reaction space 134, followed by supplying water the batch substrates to react with adsorbed TMA, followed again by providing an inert gas to purge the reaction space. The controller 115 can be configured to repeat the sequence of providing TMA, purging, providing water, and purging to form an aluminum oxide having a desired thickness. Further details of an example of a gas delivery system that can be used for the reactant source 137b for conducting ALD is illustrated and described with respect to FIG. 17B below.

In some implementations the batch process chamber 116 shown in FIG. 16 can be configured to deposit the SAM layer. The reactant source 137c can be configured to contain an SAM monomer such as n-decyltrichlorosilane. In some implementations the controller 115 is configured to open the valve 139c to supply n-decyltrichlorosilane to the batch substrates. In some implementations multiple SAM monomers can be supplied to the reactor. The reactant source 137c can also be configured to contain an oxygen source vapor such as oxygen and can also include an excited species generator. The reactant source 137c can be additionally be configured to contain an inert gas, such as nitrogen for purging the reaction space after the SAM layer is formed. In some implementations the controller 115 is configured to generate ozone or oxygen plasma to clean the reaction space after the substrates have been removed. Further details of an example of a gas delivery system that can be used for the reactant source 137c for conducting SAM deposition is illustrated and described with respect to FIG. 17C below.

FIG. 17A is a schematic illustration of an example of a batch process chamber configured for release etching. The batch process chamber 116 can be configured with the reactor shell 130, platform 128 and related components as described above with respect to FIGS. 15A-15C. The batch process chamber 116 is a module or tool that includes a reactant source 137a in the form of a gas delivery system for providing an etchant to the reaction space 134 defined by the reactor shell 130 and platform.

The etchants chosen and the form of the reactant source 137a depend upon the sacrificial material employed in the fabrication of electromechanical systems devices. Fluorine-based etchants, such as XeF₂, can selectively etch certain metallic and semiconductor sacrificial materials, such as tungsten (W), molybdenum (Mo) or silicon, without removing other exposed materials in an electromechanical systems device, such as silicon oxide, aluminum oxide and aluminum. The illustrated implementation includes a vessel holding solid XeF₂ crystals and gas lines, valves, buffers and gas sources configured to vaporize and deliver etchant vapor to the reaction space 134. In particular, vapor and inert carrier gas (such as the illustrated nitrogen or N₂ gas) are drawn into Buffer 1, which serves as an expansion chamber to aid vaporization of the XeF₂ crystals. The pressure in Buffer 1 is reduced by way of a pump. Buffer 1 can periodically feed vaporized XeF₂ to Buffer 2, which has a smaller volume than Buffer 1, in which co-etchants (such as the illustrated oxygen or O₂ gas) and inert carrier gases can be mixed before being fed to the reaction space 134. The cluster tool's controller 115 (FIG. 11) can include programming to conduct the etch release process as described.

In some implementations the pressure in the etch reaction space 134 during processing is from about 0.1 to about 5 Torr. In some implementations the release etch takes from about 10 minutes to about 60 minutes for the removal of sacrificial material (such as molybdenum) from a batch of substrates. The exhaust 140 from the reaction space 134 can be closed off after the target pressure is reached, and remain closed after etching reactant vapors are provided from the reactant source 137a. The substrates can soak in the backfilled reaction space 134 until the etchants are exhausted, in which case another cycle of vaporization and backfill can be conducted, or until the sacrificial material is fully etched.

In some implementations the parts defining the reaction space 134 of the release etch process chamber 116, such as the reactor shell 130, the platform 128 and the rack 118, are constructed out of materials that are resistant to XeF₂-based etchants and any reaction by-products, such as aluminum, aluminum alloy, SS316, or Inconel. Quartz may be used, and may be coated with a coating that is further resistant to XeF₂-based etchants, such as aluminum oxide or yttrium oxide. Aluminum oxide can be used, for example, as a window material for viewing the interior of these components. XeF₂ can react with water to form corrosive compounds such as HF that can undesirably etch the substrate and reaction space materials. The cluster tool can be operated to minimize the risk of water contamination of the etch process chamber, such as from neighboring ALD process chambers and SAM chambers as described below, to avoid formation of undesirable by-products.

FIG. 17B is a schematic illustration of portions of an example of a batch process chamber configured for ALD. The batch process chamber 116 can be configured with the reactor shell 130, platform 128 and related components as described above with respect to FIGS. 15A-15C. The batch process chamber 116 is a module or tool that includes a reactant source 137b in the form of a gas delivery system for providing ALD reactants and purge gas to the reaction space 134 defined by the reactor shell 130 and platform.

The reactants and the form of the reactant source 137b depend upon the desired material to be deposited. The illustrated implementation includes a vessel holding a metal reactant, such as trimethyl aluminum (TMA, (CH₃)₃Al) and an oxygen source vapor, such as water. The TMA and water can be delivered to the reaction space by alternate and sequential pulses by high speed valves, with intervening removal of reactants from the reaction space 134, such as by providing an inert gas to purge the reactor of the previous reactant. As TMA is naturally liquid, the vessel can also serve as a vaporizer, such as a bubbler. The TMA can adsorb on surfaces of the batch of substrates in one reactant pulse, and the water can react with the adsorbed species in a subsequent pulse to form a self-limited monolayer of aluminum oxide. In some implementations the reactants flow through the reaction space 134 to the reaction space's exhaust 140; in some implementations, the exhaust 140 is closed and the reaction space 134 backfilled in one or more of the reactant pulses. Multiple cycles can be performed to form an aluminum oxide layer having a desired thickness. In some implementations, the aluminum oxide layer has a thickness of about 3 Å to about 50 Å. In some implementations, the aluminum oxide layer has a thickness of about 40 Å to about 90 Å. In some implementations the aluminum oxide layer can be used as a seed layer to promote the subsequent formation of the SAM. The cluster tool's controller 115 (FIG. 11) can include programming to conduct the ALD process as described.

In some implementations the pressure in the reaction space during the ALD process is from about 100 mTorr to about 1 Torr. In some implementations the deposition of the ALD layer or seed layers takes between about 10 and 80 minutes.

In some implementations multiple process gas inlets can be used with the reaction space to avoid mixing the process gases in the inlet lines.

In some implementations the ALD reaction space is made of a material that is resistant to TMA, water, and any reaction by-products, such as aluminum, aluminum alloy, SS316, quartz, or titanium and/or aluminum oxide. The surface of these materials may be treated, for example, through coatings (e.g., aluminum oxide or yttrium oxide), anodization or roughening (e.g., to prevent film peeling). The roughness can be 3 μm Ra. In some implementations the reaction space is periodically cleaned to remove aluminum oxide formed on the reaction space surfaces.

FIG. 17C is a schematic illustration of portions of an example of a batch process chamber configured for SAM deposition. The batch process chamber 116 can be configured with similar reactor shell 130, platform 128 and related components to those described above with respect to FIGS. 15A-15C. The illustrated batch process chamber 116 may include temperature control elements 170 for controlling temperature therein. For example, temperature control elements 170 can comprise infrared (IR) heaters around the shell 130, and the shell can be at least partially transparent to IR light. In some implementations, control elements 170 can comprise piping from a chiller to control temperature that flows around or through the shell 130, to provide conductive or convective temperature control. Control elements 170 can be used for controlling the temperature of the process chamber configured for SAM deposition. For example, the wall temperature of the process chamber may be controlled to approximately 30-40 degrees C. for a SAM process using DTS reactant. The batch process chamber 116 is a module or tool that includes a reactant source 137c in the form of a gas delivery system for providing monomers capable of forming self-assembled monolayers (SAMs).

The illustrated implementation of the reactant source 137c includes a vessel for providing vapor phase monomer n-decyltrichlorosilane (DTS), a vessel holding water, expansion chambers for vaporizing each of these sources, inert carrier gas provided to the expansion chambers, and a source of ozone for post-deposition cleaning of the reaction space 134 defined by the shell 130 and the platform 128.

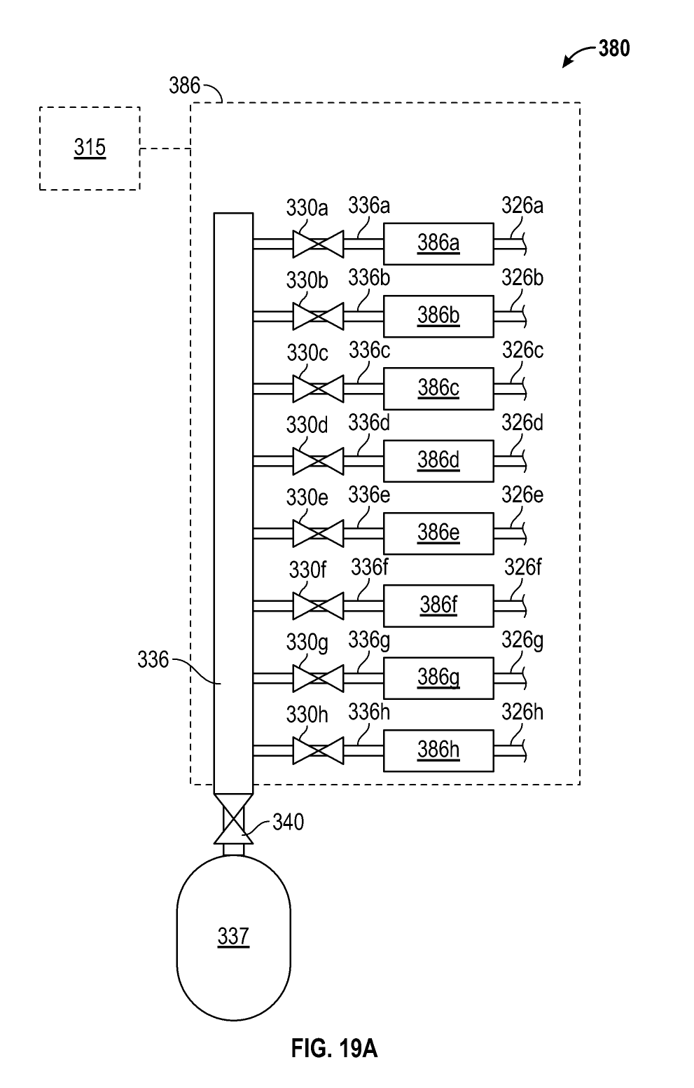

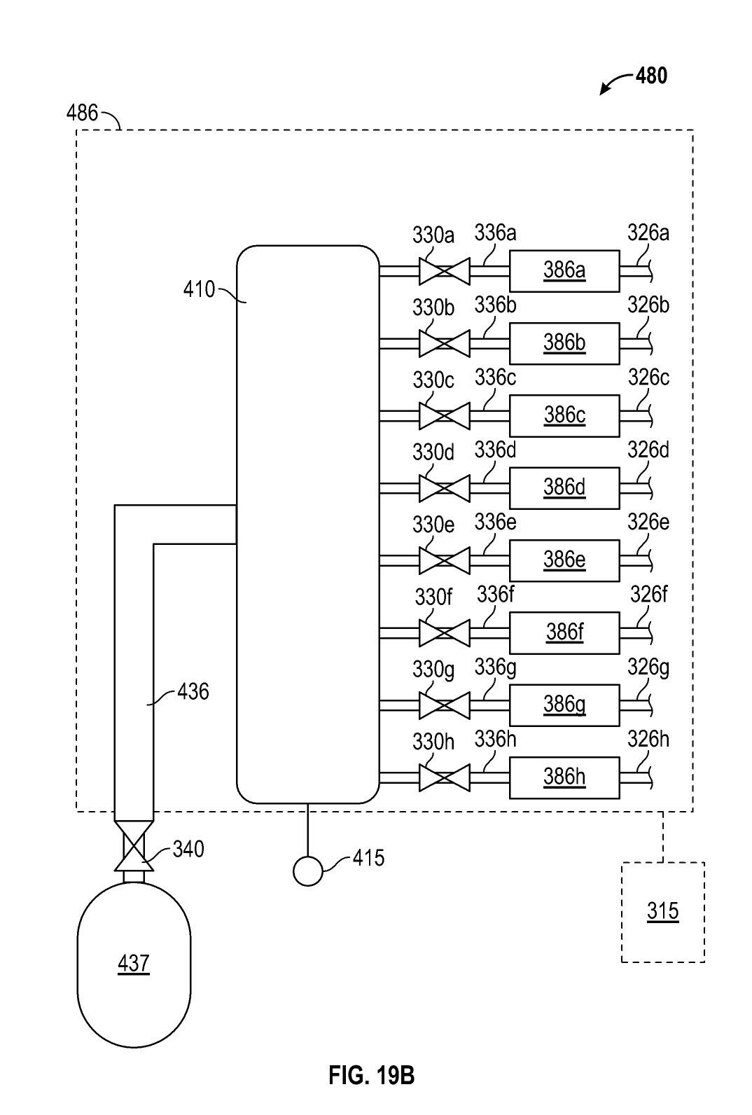

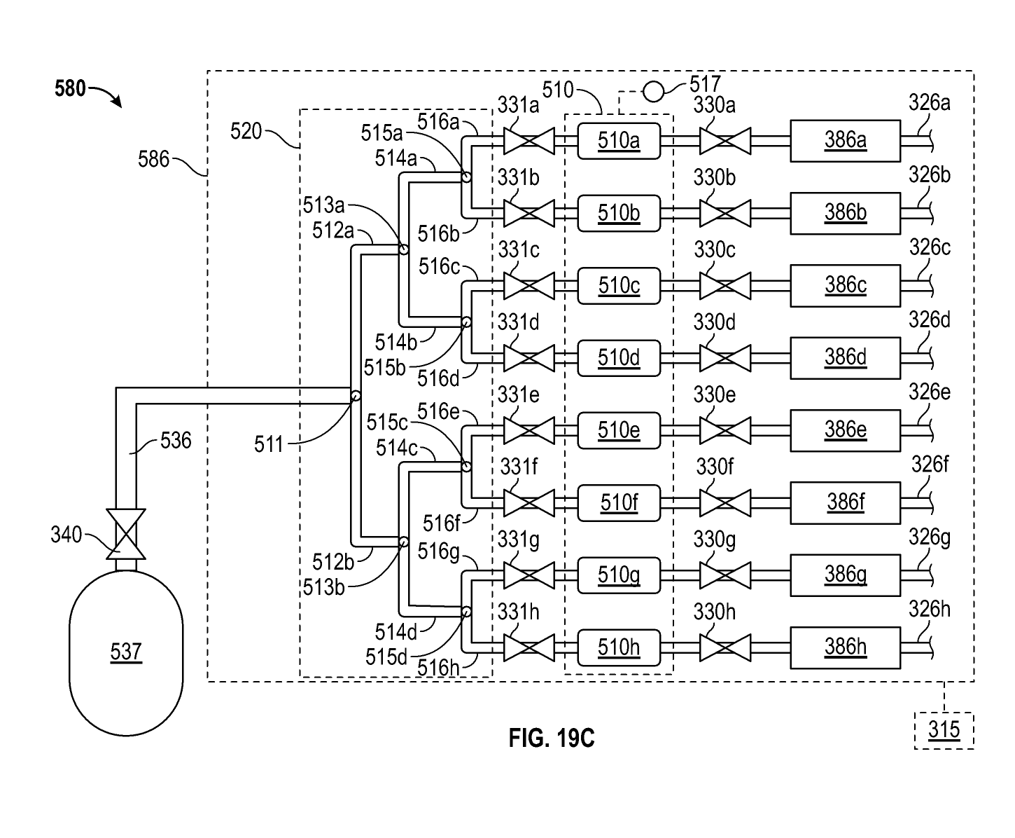

FIG. 18A is a schematic cross section of an example of an apparatus for batch processing. A cluster tool 180 includes a load lock chamber 182, a transfer chamber 184, and a plurality of process chambers 186 (one shown), each configured to process multiple substrates 120. The one or more process chambers 186 can include a plurality of process subchambers 186a-186h. The subchambers 186a-186h can be horizontally and vertically stacked over one another, to form a stack of subchambers. In the illustrated implementation, process chamber 186 defines an outer chamber surrounding the plurality of process subchambers 186a-186h.

The load lock chamber 182 can be configured to handle a boat, rack, cassette, or otherwise configured to handle multiple substrates 120. The load lock chamber 182 can be configured to receive the multiple substrates through a door 181 from an outside loading platform (not shown). The substrates 120 can be transferred from the load lock chamber 182 through a door 183 into the transfer chamber 184 using a robot 185. The transfer chamber 184 is in selective communication with the load lock chamber 182 and the plurality of process chambers 186. The cluster tool 180 can include similar components and function substantially similarly as the other implementations of the cluster tools described herein, such as cluster tools 110, 150, 160, and 170 described above with respect to FIGS. 11-14, although many of the components from these cluster tools are omitted in FIG. 18A for brevity. For example, the cluster tool 180 can include one or more controllers, pumps, reactant source(s), gas delivery systems and subsystems, and other components included or interacting with the load lock chamber 182, transfer chamber 184, and processing chamber 186 (including the process subchambers 186a-186h).

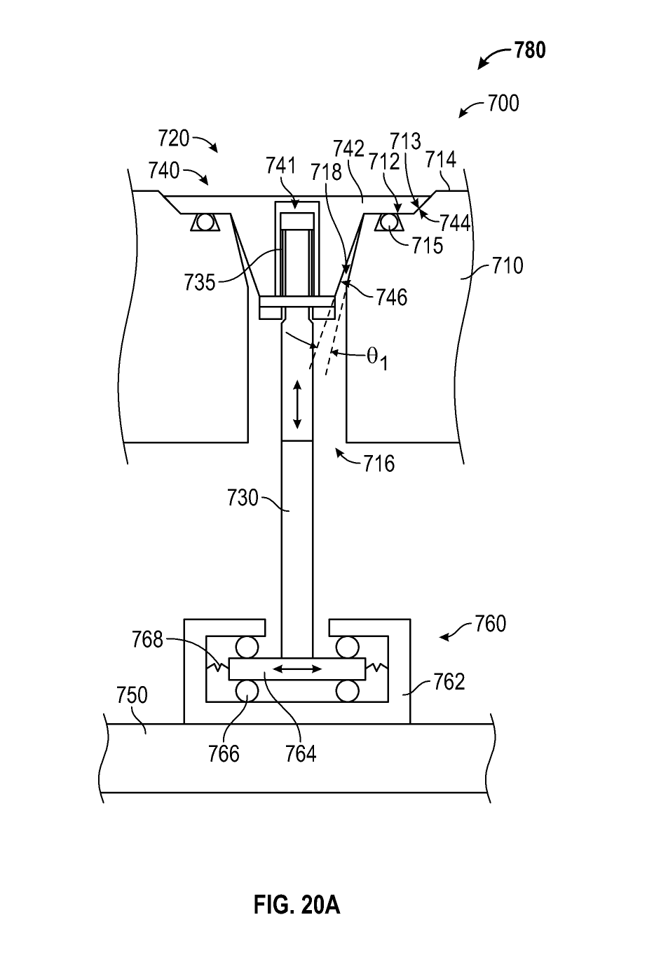

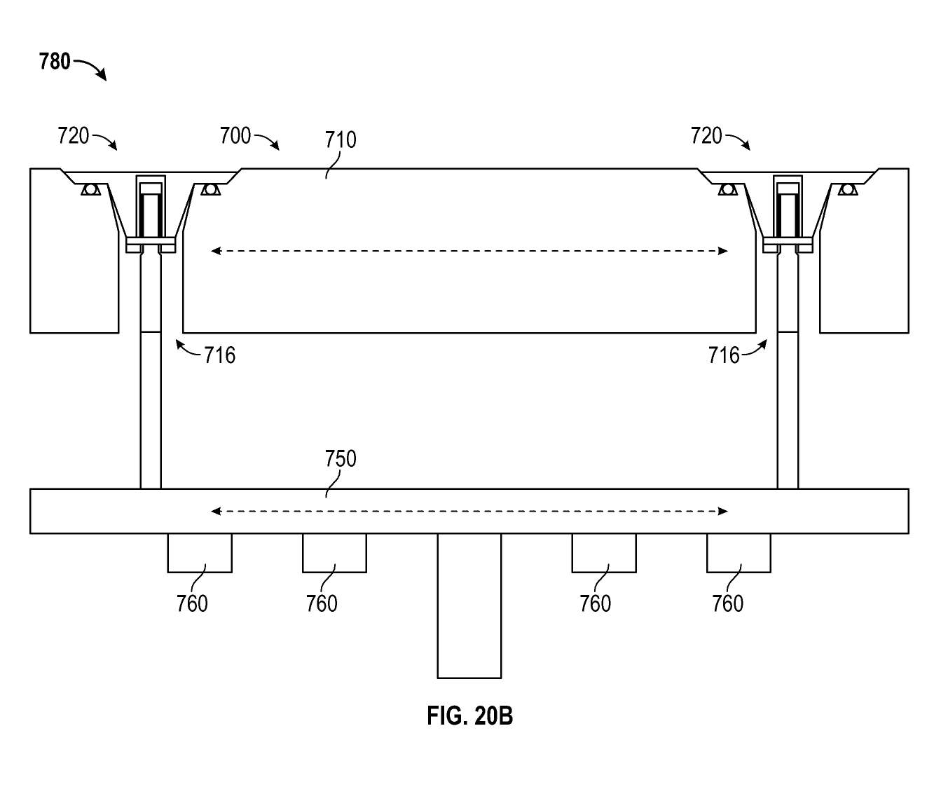

Each process subchamber 186a-186h can be configured to individually process a subset of the multiple substrates 120. In some implementations, each process subchamber 186a-186h can be configured to process a single substrate. Each process subchamber 186a-186h can include one or more substrate supports 188a-188h to support a substrate. The substrate supports 188a-188h can include a base, one or more pins (e.g., lift pin assemblies, such as those described in more detail below with respect to FIGS. 20A and 20B), flanges, and/or other structure, or combinations thereof, suitable for providing support to a substrate within the process subchambers 186a-186h. The process chambers with subchambers described herein, such as process chamber 186 and its subchambers 186a-186h, can be implemented within a cluster tool, such as the illustrated cluster tool 180, or within other single-process or multiple-process environments, such as a standalone processing tool that is not integrated with other processes in a cluster tool. Additionally, the process chambers with subchambers described herein can be configured to perform any of a number of processes on substrates, such as the ALD, SAM, etch/release processes described herein with respect to process chambers with or without subchambers, as well as other types of processes.

FIG. 18B is a schematic cross section of another example of an apparatus for batch processing. A process tool 280 can include a process chamber 286 which can include a plurality of process subchambers 286a-286h. In the illustrated implementation, the process chamber 286 defines an outer chamber surrounding the plurality of process subchambers 286a-286h. The process chamber 286 can be implemented within a cluster tool, such as tool 180 (FIG. 18A) or the batch cluster tools 110, 150, 160, 170 of FIGS. 11-14 described above. The process subchambers described herein, such as subchambers 286a-286h, can be sufficiently isolated, to allow for individual processing of a separate substrate (or subset of substrates) within each subchamber, while still including common features with respect to each other. For example, the process tool 280 can include one or more common sources for process gas delivery, such as a common gas source 237, with a common primary supply (e.g., conduit) 236 supplying a plurality of parallel secondary reactant inlets (e.g., conduits) 236a-236h in communication with individual ones of the subchambers 286a-286h. The process tool 280 can include a common vacuum source and/or exhaust with respect to all of the interior volumes of the process subchambers 286a-286h. For example, tool 280 can include a common exhaust line 226 with parallel exhaust branches 226a-226h providing communication between the common exhaust line 226 and each of the subchambers 286a-286h. A common exhaust pump 227 can be connected to exhaust line 226. The process tool 280 can include one or more additional common reactant sources, similar to reactant source 237, to provide additional gas delivery that is separate from the first gas source 237, but common with respect to the subchambers. Such additional reactant source(s) can be mixed with the first reactant source 237 within each subchamber, upstream of each subchamber, or can be delivered in separate, sequential processes without mixing. In some implementations, one or more of separate gas delivery, vacuum, and/or exhaust structures can be in separate communication with respect to each of the process subchambers.

The process subchambers described herein can be sealed with respect to each other, apart from communication with their common inlet and outlet assemblies, during processing. In some implementations, the process gas delivery, vacuum and/or exhausts, and/or other process features, such as temperature, can be separately and selectively controlled with respect to each of process subchambers, to allow individual tuning of a process performed within each of the process subchambers. Moreover, selective control of flow into and out of individual subchambers, such as through controllable valves upstream and downstream of individual subchambers, can allow selectively taking one or more subchambers off-line in the event of any malfunction or damage, while still allowing continued processing of substrates in the remaining subchambers in parallel. In some implementations, the process subchambers can be configured to allow for simultaneous, parallel processing of multiple substrates with substantially similar process conditions.

Selective communication (e.g., for substrate transfer) can be provided to the interior of each of the subchambers described herein with individual movable covers, such as a lids (FIGS. 18B-18D) or doors (FIG. 18A). In some implementations, a plurality of commonly-linked covers can be configured to simultaneously provide selective access to an interior volume of the subchambers.

Referring again to FIG. 18A, in some implementations, each of the subchambers 186a-186h are in selective communication with the transfer chamber 184 through a plurality of doors 187a-187h, respectively. Each of the doors 187a-187h can include a gate valve, swinging door, sliding door, or other suitable configuration to selectively open and close a chamber or subchamber. In some implementations, the doors 187a-187h can be linked to each other (electronically and/or mechanically) to simultaneously open or close. In the illustrated implementation, the doors 187a-187h open from the subchambers 186a-186h into the transfer chamber 184; in other implementations, the subchambers can be entirely surrounded by the walls of the outer chamber of the process chamber, such that a separate door (not shown) separates the outer chamber from the transfer chamber.

FIGS. 18C and 18D are partial schematic cross sections of the apparatus for batch processing of FIG. 18B showing different states of operation. Subchambers 286c-286h of FIG. 18B are omitted for convenience; the features of subchambers 286a-286b shown in FIGS. 18C-18D can be implemented within subchambers 286c-286h of FIG. 18B. In the illustrated implementation, the interiors of the subchambers 286a-286b are in selective communication with the exteriors of the subchambers 286a-286b through a plurality of movable lids 287a-287b, respectively. Lids 287a-287b can be moved between a lowered or closed position (FIG. 18C) and a raised or opened position (FIG. 18D), as shown by arrows 901. Lids 287a and 287b can cover substrates supports or bases 289a and 289b, to form inner process volumes within subchambers 286a and 286b, respectively. Lids 287a and 287b can seal with bases 289a and 289b, respectively, or can move proximate to bases 289a and 289b without contacting or sealing therewith. Access to subchambers 286a and 286b for loading/unloading substrates can be provided through a larger, common door 283 extending through a wall of process chamber 286 (FIG. 18B), or through individual doors that separate the process chamber from each subchamber.

Implementations of process tools that include process subchambers, such as subchambers 186a-186h (FIG. 18A) or 286a-286h (FIG. 18B), within a common process chamber can reduce the amount of time to evacuate, purge, or process multiple substrates relative to some other tools with similar processes, such as a running a similar process on a batch of substrates within a shared volume where the substrates are in open communication with one another. One reason for this time reduction is that the total, combined volume of the interior volumes of the process subchambers may be less than the overall volume within a batch process chamber performing a similar process on a batch tool. This reduced overall volume within the process subchambers can also reduce process gas consumption, and/or reduce the size of the pumps, valving, and other components that evacuate, purge and/or provide process gas to the subchambers, relative to that of a similar batch processing tool where the substrates are in open communication with one another.

Implementations of process tools that include process subchambers may include valves, accumulators, flow controllers, pressure controllers, sensors, and/or any of a number of different fluid power components to control the flow of gas to and from the subchambers. In some implementations, one or more accumulators may be positioned downstream of the reactant source, and upstream of the subchambers, to affect the flow the reactant into the subchambers. Such accumulator(s) can include a common pipe or buffer, or can include individual buffers, one for each subchamber. One or more valves may be positioned upstream and/or downstream of the accumulator, to selectively flow reactant to and from the accumulator(s). The valves can be controlled to vary the amount of reactant flowed into the subchambers (e.g., dosage) in a number of different ways, such as with time control, volume control, or pressure control.

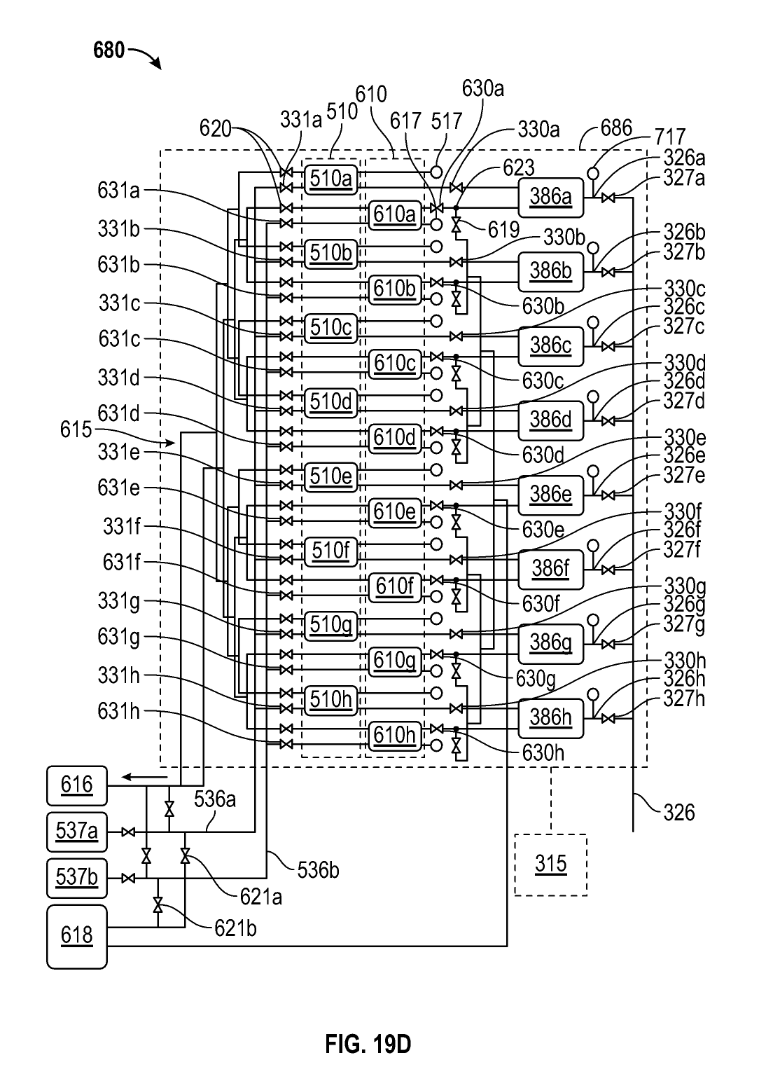

FIG. 19A is a schematic of an example of an apparatus for batch processing. A process tool 380 with a process chamber 386 can include a plurality of subchambers 386a-386h in communication with exhaust lines 326a-326h and secondary reactant conduits 336a-336h, respectively. The subchambers 386a-386h can be similar to subchambers 186a-186h (FIG. 18A) or 286a-286h (FIG. 18B) or others described herein. Any of these subchambers can be configured to process large format rectangular substrates described herein. A common primary conduit 336 can supply reactant to the secondary conduits 336a-336h from a common reactant source 337. The process tool 380, chamber 386, subchambers 386a-386h, exhaust lines 326a-326h, primary conduit 336, secondary reactant conduits 336a-336h, and gas source 337 can function substantially similar to the tools, chambers, subchambers, exhaust lines, primary conduits, secondary conduits, and gas sources described herein with respect to FIGS. 18A-18D. The process tool 380 can include other elements of the tools shown in FIGS. 18A-18D, including some omitted for brevity in FIG. 19A, and vice versa. Various components and aspects of process tool 380 can be controlled by a controller 315, which can be similarly implemented with the other process tools and subchambers described herein.

A plurality of outlet valves 330a-330h can be positioned downstream of the primary conduit 336. Outlet valves 330a-330h can be configured to selectively flow reactant from the primary conduit 336 into subchambers 386a-386h, respectively, such that they control outlet flow from the accumulator(s). Outlet valves 330a-330h can be controlled by the controller 315 to open and close simultaneously, or at different times, with respect to each other. Outlet valves 330a-330h can allow one or more of subchambers 386a-386h to be taken individually offline, for example, while the others of subchambers 386a-386h continue to process substrates. A shut-off valve 340 can be positioned downstream of the gas source 337 and upstream of the primary conduit 336. Shut-off valve 340 can be configured to selectively flow reactant into the primary conduit 336.

In a time control dosage operation, outlet valves 330a-330h can be maintained in a closed position while reactant is allowed to flow into primary conduit 336 for a period of time (e.g., by keeping shutoff valve 340 open). After the period of time has lapsed, one or more of outlet valves 330a-330h can be opened, simultaneously or sequentially, allowing a dose of reactant to flow from one or more of outlet valves 330a-330h into subchambers 386a-386h, respectively. In some implementations, the outlet valves 330a-330h can be opened at different times (for example, sequentially, or staggered) with respect to each other, to reduce pressure drop within the primary conduit 336. After another period of time has lapsed, and a dose of reactant has been supplied into the one or more subchambers 386a-386h, the one or more outlet valves 330a-330h can be closed, simultaneously or sequentially. Through such a time control dosage operation, for relatively low pressure precursors, such as naturally liquid or solid precursors commonly used for ALD metallic or semiconductor precursors, vapor pressure can build in the primary conduit 336 between dosage deliveries (e.g., between ALD pulses), such that the primary conduit 336 can serve as an accumulator. It is understood that in some implementations, shutoff valve 340 can remain open during processing and only the outlet valves 330a-330h open and close.

The primary conduit 336 can have an inner cross-sectional area that is larger than an inner cross-sectional area of each of the plurality of secondary conduits 336a-336h. Such a configuration can allow for accumulation and relatively uniform distribution of flow into the multiple secondary conduits 336a-336h. Sizing the primary conduit 336 such that it forms an accumulator and distributor, and/or using the aforementioned time control dosage operation may be beneficial, for example, in an ALD process. For example, it may be beneficial to use such a configuration when the common reactant source 337 comprises an ALD reactant, such as trimethyl aluminum, or a semiconductor or other metal source. It may also be beneficial to duplicate such a configuration for other ALD reactants, such as a common oxidizing source, such as water, such that ALD reactant is provided with a separate path to each subchamber 386a-386h. In some implementations, process tool 380 can comprise an ALD tool in which the primary conduit 336 can form an accumulator with an inner cross-sectional area that falls within a range of approximately eight to twelve times greater than the inner cross-sectional area of each of the secondary conduits 336a-336h. In some implementations (for example, when process tool 380 is an ALD tool), the inner volume of the primary conduit can form an accumulator with a volume of 0.05 to 0.5 times the total volume of subchambers 386a-386h. It is understood that for ALD and other processes requiring two reactants, the subchambers 386a-386h shown in FIG. 19A can be each connected with a separate source for each reactant, each source having a separate primary conduit, outlet valves and secondary conduits.

FIG. 19B is a schematic of an example of an apparatus for batch processing. A process tool 480 with a process chamber 486 can include an accumulator 410 positioned downstream of a common reactant source 437 and upstream of the subchambers 386a-386h. A primary conduit 436 can supply reactant from the common gas source 437 to the accumulator 410. The accumulator 410 can comprise a flask, canister, cylinder, or other container with an inner volume suitable to store reactant supplied from gas source 437, thus serving as a buffer chamber. One or more sensors 415, such as a pressure, temperature, or other sensor, may be in communication with accumulator 410, to monitor an environmental condition of accumulator 410, such as its internal pressure. One or more sensors can be similarly employed within the other accumulators described herein.

The volume of the accumulator 410 can be selected to store sufficient volume of a reactant relative to a process performed within subchambers 386a-386h. For example, the accumulator 410 can include an inner volume that falls within a range of approximately 0.5 to 20 times, or in some implementations, 0.5 to 5 times a total inner volume of all of the subchambers 386a-386h. Using a single accumulator supplying all the subchambers, such as accumulator 410 may provide similar accumulation and distribution function as primary conduit 336, when primary conduit 336 is configured to act as a buffer chamber, as described above with reference to FIG. 19A.

FIG. 19C is a schematic of an example of an apparatus for batch processing. A process tool 580 with a process chamber 586 can include an accumulator 510 positioned downstream of a common reactant source 537 and upstream of the subchambers 386a-386h. A primary conduit 536 can supply reactant from the common reactant source 537 to the accumulator 510. The accumulator 510 can include a plurality of buffers 510a-510h. The buffers 510a-510h can be similar in form as accumulator 410 (FIG. 19B), but with a smaller volume, to provide an individual buffer for each subchamber 386a-386h for a common reactant source. At least one of buffers 510a-510h can be positioned upstream of each outlet valve 330a-330h. Tool 580 can include a plurality of inlet valves 331a-331h, with each inlet valve 331a-331h positioned upstream of each buffer 510a-510h, respectively. Each inlet valve 331a-331h can be configured to selectively flow reactant into each of the buffers 510a-510h. A plurality of exhaust valves can be positioned downstream of, and configured to selectively control the flow of gas from subchambers 386a-386h, respectively, through exhaust lines 326a-326h into a common exhaust. Such exhaust valves may be maintained closed during a soak/saturation process, such as release etch, or opened during a flow-through operation, such as ALD. An implementation with such exhaust valves is shown in FIG. 19D and described further below.

In some implementations, process chamber 586 can be configured to perform a volume-control dosage operation. In a volume-control dosage operation, the volume of the buffers 510a-510h can be selected to store sufficient volume of a reactant relative to a process performed within subchambers 386a-386h. For example, each of buffers 510a-510h can include an inner volume that falls within a range of approximately 0.5 to 1.0 times an inner volume of each of the subchambers 386a-386h, for an etch process. In use, the outlet valves 330a-330h can be maintained in a closed position while reactant is flowed into one or more of buffers 510a-510h for a period of time (e.g., by keeping shutoff valve 340, and one or more of inlet valves 331a-331h open). After the period of time has lapsed, one or more, or in some implementations, all of valves 330a-330h can be opened, sequentially, or simultaneously, allowing a dose of reactant to flow from one or more of valves 330a-330h into subchambers 386a-386h, respectively. An exhaust valve (e.g., exhaust valves 327a-327h; shown in FIG. 19D) downstream of each subchamber 386a-386h can be maintained in a closed position during flow of the dose of reactant into subchambers 386a-386h, and/or during processing of a substrate within subchambers 386a-386h. For example, an exhaust valve may close subchambers 386a-386h in a soak or saturation process such as release etch and/or SAM.

After another period of time has lapsed, and a dose of reactant has been supplied into the one or more subchambers 386a-386h, the one or more valves 330a-330h can be closed, simultaneously or sequentially. In some implementations, the above steps can be repeated, to re-fill one of buffers and provide multiple doses from the buffer into a corresponding subchamber, for a single process cycle within a subchamber. The volume of buffers 510a-510h can generally be selected to allow a sufficient dosage of reactant to the subchambers 386a-386h for the process being performed therein. Implementing a volume-control operation may be beneficial, for example, in a release etch process. For example, such a configuration may be beneficial when the common reactant source 437 comprises an etchant source, such as a fluorine-based etchant, such as xenon difluoride. Additional description of a release etchant process, and the benefits to providing buffers to allow for expansion of etchants upstream of a process chamber is described above with reference to Buffers 1 and 2 shown in FIG. 17A.

Continuing to refer to FIG. 19C, tool 580 can include a reactant distribution manifold 520 configured to provide fluid communication between the common reactant source 537 and each of subchambers 386a-386h. The primary conduit 536 can be connected to the common reactant source 537. A first connection point 511 can be positioned at a downstream end of the primary conduit 536. The first connection point 511 can divide flow from the primary conduit 536 into at least two secondary conduits 512a, 512b. A plurality of second connection points 513a, 513b can be connected at downstream ends of the secondary conduits 512a, 512b. Each second connection point 513a, 513b can divide flow from the corresponding secondary conduit 512a, 512b into at least two tertiary conduits 514a-514d. A plurality of third connection points 515a-515d can be connected at downstream ends of the tertiary conduits 514a-514d. Each third connection point 515a-515d can divide flow from the corresponding tertiary conduit 514a-514d into at least two quaternary conduits 516a-516h. In the illustrated implementation, the reactant distribution manifold 520 includes one first connection point 511, two second connection points 513a, 513b, and four third connection points, 515a-515d, for a total of two secondary conduits 512a, 512b, four tertiary conduits 514a-514d, and eight quaternary conduits 516a-516h in communication with eight subchambers 386a-386h. In some implementations, flow paths from the common source of reactant 537 to each of the eight buffers 510a-510h, or to each of the eight subchambers 386a-386h, can be approximately equal, due to the branching inlet tree. The reactant distribution manifold 520 can increase the uniformity of reactant supplied to the different subchambers 386a-386h, and can be similarly employed within the other subchambers described herein.

FIG. 19D is a schematic of an example of an apparatus for batch processing. A process tool 680 with a process chamber 686 can be in communication with a first common reactant source 537a and a second common reactant source 537b. Process tool 680 can be similar in many ways and provide similar function in many ways to process tool 580 in FIG. 19C. Process tool 680 can be configured to provide common reactant from the common reactant sources 537a, 537b in parallel to the subchambers 386a-386h. The tool 680 can include the first accumulator 510 positioned downstream of the first common reactant source 537a and a first primary conduit 536a, and upstream of the subchambers 386a-386h, and a second accumulator 610 positioned downstream of the second common reactant source 537b and a second primary conduit 536b, and upstream of the subchambers 386a-386h. The first and second accumulators 510 and 610 can include the first and a second plurality of buffers 510a-510h and 610a-610h. The second plurality of buffers 610a-610h of the second accumulator 610 can be similar in many ways to the first plurality of buffers 510a-510h of the first accumulator 510. Inlet valves 631a-631h and outlet valves 660a-630h can be provided to selectively flow reactant into buffers 610a-610h, similar to inlet valves 331a-331h and outlet valves 330a-330h, as described above, for example, with reference to FIG. 19C. Pressure sensors 517, 617, or one or more additional sensors, can be included to monitor pressure or other environmental conditions within buffers 510a-510h, and 610a-610h, respectively, or other components within tool 580. For example, sensors 717 may be positioned downstream of each of subchambers 386a-386h, to measure pressure or other conditions downstream or within each of subchambers 386a-386h. A plurality of exhaust valves 327a-327h can be positioned downstream of, and configured to selectively control the flow of gas from subchambers 386a-386h and through exhaust lines 326a-326h, respectively and into a common exhaust 326.

The first reactant source 537a and the second reactant source 537b can include reactants to form a self-assembled monolayer (SAM) on a substrate. In some implementations, the first reactant source 537a can include an organic source chemical, such as n-decyltrichlorosilane (DTS), and the second reactant source 537b can include an oxygen source, such as water. An inner volume of each of the first plurality of buffers 510a-510h may be sized, relative to an inner volume of each of the second plurality of buffers 610a-610h, based upon the type of reactant in reactant sources 537a, 537b. For example, in an implementation in which the first reactant source 537a includes an organic source chemical, and the second reactant source 537b includes an oxygen source with a higher vapor pressure than the organic source chemical, an inner volume of the one of the first buffers 510a-510h can be between approximately five and fifteen, or in some implementations, between about eight and twelve times greater than an inner volume of one of the second buffers 610a-610h. The inner volume of each of the first plurality of buffers and second plurality of buffers can also be sized relative to the inner volume of the subchambers. For example, because DTS has a relatively lower vapor pressure, the buffer size can be similar to the corresponding process subchamber. In some implementations, for DTS, the inner volume of each buffer can be approximately 0.1-2.0 times the size of the corresponding subchamber. In some implementations, for DTS, the inner volume of the buffers can be 0.2-0.5 times the size of the corresponding subchamber. For water, the buffer size can be smaller still; for example, the inner volume of each buffer can be approximately 0.01-0.1 times the inner volume of the corresponding subchamber.

Process tool 680 can be configured to perform a pressure-control dosage operation from reactant source 537a and/or 537b. In such an operation, the control system 315 can be configured to close outlet valve 330a, and open inlet valve 331a, to allow flow of reactant from the reactant source 537a into buffer 510a. The control system 315 can monitor pressure within buffer 510a with pressure sensor 517. After pressure within the buffer 510a reaches a threshold, the inlet valve 331a is closed, and the outlet valve 330a is opened, to flow a pressure-controlled dose of reactant from the buffer 510a into the subchamber 386a. The exhaust valve 327a can be maintained in a closed position during flow of the dose of reactant into subchamber 386, and/or during processing of a substrate within subchamber 386a. For example, the exhaust valve 327a may be closed during a soak or saturation process such as SAM or release etch. Similar operations can be performed on any of subchambers 386a-386h, using inlet valves 331a-331h, outlet valves 330a-330h, and exhaust valves 327a-327h, simultaneously or sequentially with respect to each other. Additionally, similar operations can be performed to provide a pressure-controlled dosage of reactant into subchambers 386a-386h from the second reactant source 537b, through buffers 610a-610h, using inlet valves 631a-631h, outlet valves 630a-630h, exhaust valves 327a-327h, and the pressure sensor 617. A pressure-control dosage operation may be beneficial within some processes, such as a SAM process. It will be understood that a pressure-control dose operation can be similarly employed with processes that may use precise dosing of two or more reactants, such as a SAM process, using the apparatus of FIG. 19D, or a single reactant, such as an etch process, using the apparatus shown in FIG. 19C.

The inlet and outlet valves that control reactant flow into the subchambers described herein can include any of a number of types of valves suitable for the processes within the subchambers. For example, implementations in which valves (e.g., valves 630a-630h and 631a-631h) are used to control the dose of a higher vapor pressure reactant, such as water (e.g., in a SAM process), the inlet valve and/or the outlet valve may have a response time of approximately 5-30 ms, due to the higher vapor pressure. Implementations in which valves (e.g., valves 530a-530h and 531a-531h) are used to control the dose of a relatively lower vapor pressure reactant, such as DTS (e.g., in a SAM process), the inlet valve and/or the outlet valve may have a relative longer response time of approximately 70-150 ms.

In some implementations, the outlet valves can be closed before the pressure is balanced within the subchambers to prevent back diffusion from the subchambers into the buffers. For example, the flow rate through the outlet valves may be approximately 10-50 times faster than the rate of diffusion. The Peclet number, corresponding to gas flow rate/diffusion speed may be used to determine an approximate discharge pressure. In some implementations, the pressure at which the outlet valves may be opened, to release a pressure-controlled dose of reactant, may correspond to a point at which the Peclet number is greater than 50. A Peclet number above 50 may correspond to a point at which back diffusion from the process subchamber to the buffer chamber is at a sufficiently low value to avoid detrimental effects to the processes being employed, such as etch release or SAM deposition.

In some implementations, wherein the first reactant source 537a comprises an n-decyltrichlorosilane (DTS) source, the control system 315 can be configured to provide pressure-controlled doses of DTS to the subchambers 386a-386h from the first buffers 510a-510h. In some implementations, outlet valves 330a-330h can be kept closed until the pressure of DTS within subchambers 386a-386h is detected by pressure sensors 517 to fall within a range of approximately 0.3 to 0.5 Torr, at which point control system 315 opens outlet valves 330a-330h. In some implementations, the DTS can be controlled with a temperature sensor to fall within a temperature range of approximately 70-90 degrees C. In some implementations, wherein the second reactant source 537b comprises a water source, the control system 315 can be configured to keep outlet valves 630a-630h closed until the pressure detected by pressure sensor 617 falls within a range of approximately 25-37 Torr, upon which outlet valves 630a-630h can be opened, providing a pressure-controlled dose of water to at least one subchamber. In some implementations, the water can be controlled with a temperature sensor to fall within 20-40 degrees C.

Continuing to refer to FIG. 19D, process tool 680 can include a gas supply 618 configured to supply a purge gas (e.g., nitrogen) to various points of process chamber 686. For example, nitrogen can be supplied from gas supply 618 through valves 621a, 621b to supply conduits 536a, 536b, respectively, to serve as a carrier gas and mix with the reactants being supplied into the buffers 510a-510h and 610a-610h. Gas supply 618 can supply nitrogen through a similar branching distribution system to the outlets of buffers 610a-610h between buffers 610a-610h and the subchambers 386a-386h by way of valves 619 to connection points 623 positioned downstream of buffers 610a-610h, to serve as a purge gas to subchambers 386a-386h. Tool 680 can include vacuum systems 615 with a vacuum source 616 and a plurality of valves 620 connected upstream of buffers 510a-510h and 610a-610h. Vacuum systems 615 can evacuate buffers of residual reactant before and between doses, to ensure accurate control of the subsequent dose provided through pressure-controlled dosage.

In some implementations, an additional gas supply can be configured to provide another gas, such as nitrogen or oxygen, into each of the buffers described herein. The additional gas supply can be controlled to a pressure within the buffers, similar to the pressure control described herein with respect to the reactants in the buffers. In some implementations, the additional gas supply can be mixed with reactant within the buffers.

FIGS. 19A-19D provide different batch process chamber configurations with stacked smaller volume subchambers for improved processing speed and uniformity. While examples are provided for each chamber for different dosage control schemes (time control, volume control and pressure control) for increasingly more dosage-sensitive examples of processes (ALD, release etch, and SAM formation), these are only examples and different dose control schemes and/or different processes can be conducted in any of the example apparatuses of FIGS. 19A-19D. Additionally, the process chambers and their corresponding subchambers shown in FIGS. 19A-19D can be employed in a cluster tool, with these different processes and dosage control schemes implemented within different tools in the cluster. For example, a cluster tool can implement any two or three of the following chambers/processes: (1) a time-controlled does operation within subchambers of an ALD process tool on the cluster tool; (2) a volume-controlled dose operation within subchambers of a release etch process tool on the cluster tool; and (3) a pressure-controlled dose operation within subchambers of a SAM tool on the cluster tool. In some implementations, the cluster tool may include a time controlled dose operation within subchambers of an ALD tool on the cluster in combination with one or both of a volume controlled dose operation within subchambers of a release etch process tool on the cluster, and a pressure controlled dose operation within subchambers of a SAM tool on the cluster. In some implementations, a cluster tool can include two or more chambers of: a chamber having volume controlled dose operation, a chamber having time controlled dose operation, and a chamber having pressure controlled dose operation, where each chamber can include a plurality of subchambers. It is understood that doses for release, ALD, and SAM processes may also differ from the particular dose control implementations just described. For example, a cluster tool can implement a volume controlled dose operation within subchambers of a SAM tool on the cluster.

FIG. 20A is a partial schematic cross section of an example of a lift pin and substrate support structure for loading and unloading a substrate in a process chamber. An apparatus 780 can include a substrate support 700 including a base 710. A lift pin seat 712 formed in the base 710 can be recessed with respect to (e.g., extending into) an upper surface 714 of the base 710. A pin hole 716 can extend through the recessed lift pin seat 712 and the base 710. The pin hole 716 can include a tapered opening 718 that widens towards the upper surface 714 and opens to the lift pin seat 712.

Apparatus 780 can include a self-centering lift pin assembly 720 configured to extend through the pin hole 716. The lift pin assembly 720 can include a lift pin shaft 730 and a pin head 740. The lift pin shaft 730 can be received by a pin head channel 741 extending from a lower surface of the pin head 740. The lift pin assembly 720 can be mounted on a lift pin support 750, such that when lift pin support 750 is moved relative to the substrate support 700, the lift pin assembly raises and lowers a substrate supported by pin head 740, relative to the base 710. In some implementations, the pin head 740 and lift pin shaft 730 can be resiliently or elastically connected to each other, for example, with a spring 735.

Pin head 740 can include a flanged upper portion 742 configured to extend over and engage with seat 712 of substrate support 700. The flanged upper portion 742 of pin head 740 can include an outer tapered surface 744 configured to engage with a corresponding tapered portion 713 of seat 712. An o-ring or similar sealing element 715 that can provide sealing between pin head 740 and seat 712 of substrate support 700. Pin head 740 can include an inner tapered surface 746 configured to face the tapered opening 718 of the pin hole 716. The engagement between the inner tapered surface 746 of the pin head 740, and the tapered opening 718 can provide a self-centering function, to compensate for relative thermal expansion and allow proper seating for the pin head 740. Such relative thermal expansion can arise, for example, due to differences in thermal expansion between substrate support 700 and lift pin support 750 during processing. In some implementations, the angle of tapered surface 746 and tapered opening 718 can be different with respect to each other, such that an angle θ1 is formed therebetween, as shown, to further prevent misalignment. Angle θ1 can fall in a range, for example, between approximately 2 and 25 degrees. In another implementation, θ1 can be between approximately 2 and 15 degrees.

In some implementations, a movable element 760 can be attached to the lift pin shaft 730 and the lift pin support 750. The movable element 760 can be configured to allow for relative lateral movement between the lift pin shaft 730 and the lift pin support 750. Such movement can be provided in any of a number of different ways, for example, with a slot, groove, cam, linear actuator, bearings, slides, or other means or mechanisms suitable to allow relative lateral movement. In the illustrated implementation, the movable element 760 includes a body 762, within which a slider 764 can laterally move using bearings 766. One or more springs or other resilient members 768 can be positioned on sides of the slider 764, to provide some resistance of movement, and to provide for a return position once any misalignment due to relative thermal expansion, for example, is removed.

In some implementations, the lift pin shaft 730 and the lift pin support 750 can be floating with respect to each other, without a direct connection therebetween. For example, a spring can be attached between the lift pin head and the substrate support, to allow the lift pin head to return to its lowered position engaged with the seat on the substrate support. The lift pin shaft can be floating within the pin head channel, allowing for independent lateral motion between the shaft and the pin head, while still allowing the lift pin shaft to raise the lift pin head when moved longitudinally. Such implementations can also reduce misalignment between the lift pin assemblies and the pin holes on the substrate support. It will be understood that a plurality of lift-pin assemblies 720 mounted on the substrate support 750 can be employed. In some implementations, the number of lift pin assemblies and/or the surface area of the pin head for each lift pin assembly can be selected to sufficiently handle large format rectangular substrates described herein. Larger format substrates generally use more lift pin assemblies, and more lift pin assemblies can be better for robot handling by reducing substrate sagging. Thinner substrates may also use more lift pin assemblies. However, it can be useful to have fewer lift pin assemblies to avoid pin marks, which may affect processing and quality of the devices made with the substrate. For example, it will be understood that typically between about 4 and 14 pin assemblies are employed for loading/unloading large format rectangular substrates as described herein. The surface area of the pin head (such as pin head 740) may range from approximately 50 to 2500 mm² to handle loading/unloading large format rectangular substrates as described herein.

FIG. 20B is schematic cross section of another example of a lift pin and substrate support structure for loading and unloading a substrate in a process chamber. The apparatus 780 can include a plurality of lift pin assemblies 720 extending through substrate support 700. A plurality of heaters 760 can be configured along the lift pin support 750 to control the temperature of the lift pin support. The heaters 760 can control the temperature of the lift pin support 750 relative to the temperature of the substrate support 700, to compensate for expansion of the substrate support 700 relative to the lift pin support 750. For example, if substrate support 700 expands, causing some degree of misalignment between the lift pin assemblies 720, the heaters can adjust the temperature (hotter or colder) of the lift pin support 750. Such adjustment in temperature of the lift pin support 750 will cause the lift pin support 750 to expand or contract, moving the lift pin assemblies 720 into better alignment with the pin holes 716 of the substrate support 700. The heaters 760 can be controlled through an open or closed loop control system, including, for example feedback from one or more sensors (e.g., temperature or position sensors). In a simple example, the temperature of the lift pin support 750 can be matched to the temperature of the base 710 if the materials are the same (e.g., aluminum). While only two lift pin assemblies 720 are shown, it will be understood that greater numbers are typically employed for loading/unloading large format rectangular substrates, as described herein.

In some implementations, the lift pin support 750 can include an upper and lower portion of two different materials, to improve the alignment with the substrate support 700. For example, the upper portion of the lift pin support can include the same material, or material with a similar coefficient of thermal expansion, as the substrate support 700, such as aluminum. Such an implementation can allow the upper portion of the lift pin support to expand similarly as the substrate support in response to changes in temperature, reducing misalignment therebetween. The lower portion of the lift pin support can include a stronger material, such as a ceramic or stainless steel, to provide added rigidity. The attachment between such upper and lower portions can be limited to a central attachment portion, with the radial portions extending outwardly therefrom allowed to “float” to prevent flexation of the upper and lower portions due to difference in thermal expansion coefficients.

In some implementations a process chamber with a reaction space for forming a SAM can be used as part of the batch tool. In some implementations a monomer for forming a SAM is used. The monomer can be an organic linear chain molecule having a hydrophobic tail and hydrophilic tail. In one implementation n-decyltrichlorosilane (DTS) and water are used to form the SAM. In some implementations the pressure in the reaction space when depositing SAMs is between about 100 mTorr and about 1 Torr. In some implementations depositing the SAMs takes between about 10 and about 90 minutes.

In some implementations the SAM reaction space can be cleaned using ozone or other reactive cleaner to prevent buildup on the walls of the reaction space. The cleaning can be performed in between processing of a batch of substrates or periodically after processing multiple batches of substrates. In some implementations ozone can be used for cleaning the surface of the ALD layer or other seed layer to remove any contaminants, such as hydrocarbons. Hydrocarbon contamination can be caused by exposure to a clean room atmosphere or breaking vacuum, or in some implementations can result from the ALD process if organic precursors are employed. The cluster tool's controller 115 (FIG. 11) can include programming to conduct the SAM deposition process as described, including any post-deposition cleaning.

An example of a suitable material for the reaction space for resistance to the post-deposition or periodic cleaning process is aluminum oxide, also known as alumina. In some implementations the SAM reaction chamber and/or process chamber can be lined with or coated with an anodized aluminum liner capable of resisting corrosion from HCl and any other by-products formed during the deposition of the SAM. In some implementations the SAM reaction chamber is resistant to ozone. In some implementations the liner can be made of sapphire, or single crystal alumina.

The process chambers and reaction spaces can be constructed of different materials based on the reactor configurations and process gases that are used. In some implementations the reaction space shell can be made out of quartz. In some implementations an IR heater can be used with a quartz or sapphire reaction space shell, particularly in implementations subject to highly oxidizing environments, such as the SAM batch process tool, in which activated oxygen species like ozone can be employed for post-deposition cleaning of the chamber. In some implementations the reaction space shell can be made out of stainless steel, titanium or aluminum. Such metal shells can include surface coatings or liners to better withstand processing associated with, for example, the release etch and ALD processes and any periodic cleaning processes for them. In some implementations the shell can be anodized aluminum, include an anodized aluminum liner or be coated with alumina. In some implementations the reaction space shell in the etch process chamber can be made out of aluminum or anodized aluminum. In some implementations the reaction space shell in the ALD process chamber can be made out of aluminum, quartz, or anodized aluminum. In some implementations the reaction space shell in the SAM process chamber can be made out of quartz, or anodized aluminum. Aluminum reactor walls can be obtained, for example, from S.U.S. Cast Products, Inc. of Logansport, Ind.

After the release/etch, the partially fabricated devices are sensitive to contaminants. For example, exposing the partially fabricated device to a clean room after the release and before the formation of the ALD layer and SAM layer can result in carbon contamination or other contaminants in the cavity that can degrade the properties of the finished IMOD device. The risk of contamination of the partially fabricated device can be lowered by handling the substrates at a reduced pressure and handling the substrates in a closed environment, such as the batch cluster tools 110, 150, 160, and 170 described above with respect to FIGS. 11-14, which can be operated at low pressures. For example, the release/etch process, ALD layer deposition, and SAM formation can all be performed in such batch cluster tools. The substrates can be kept within the vacuum environment without being exposed to the clean room atmosphere until after the antistiction layer, e.g. ALD and SAM, is formed within the cavity, thereby decreasing the likelihood of contamination of the partially fabricated device. Additionally, conducting all three processes of release, ALD and SAM deposition within the same tool decreases the amount of substrate handling post-release, when the devices are sensitive to damage.

In some implementations during processing the pressure in the inner process chamber is greater than the pressure in the outer process chamber during processing. For example, in the implementation of FIGS. 18A-19D, pressure within the process subchambers can be greater than the pressure in the surrounding process chambers. Similarly, in the implementations of FIGS. 15A-16, the pressure in the reaction space 134 is greater than the pressure in the process chamber 116 and transfer chamber 114, and the pressures in the process chamber 116 and transfer chamber 114 can be roughly the same. While the examples of FIGS. 18A-19D are not discussed in detail below, one having ordinary skill in this art will appreciate that similar considerations for those discussed below for the implementations of FIGS. 15A-16 apply to the implementation of FIGS. 18A-19D.

In some implementations when transferring substrates the transfer chamber 114 pressure is greater than the pressure in the process chamber 116 and reaction space 134. In some implementations the pressure in the reaction space 134 is lowered before the reaction space 134 is opened to the process chamber 116. In some implementations the pressure in the reaction space volume 134 during processing is greater than about 10⁻² Torr, while the pressure in the process chamber 116 and transfer chamber 114 when transferring substrates is less than about 10⁻⁴ Torr. In some implementations the pressure in the process chamber 116 and transfer chamber 114 when transferring substrates is less than about 10⁻⁷ Torr. In some implementations the pressure in the process chambers and transfer chamber when transferring substrates can be between about 10⁻⁵ Ton and 10⁻⁸ Torr. In some implementations transferring the substrates includes transferring the substrates from a source chamber to a destination chamber, wherein the source and destination chambers and any chamber in between the source and destination chambers are maintained at a pressure of less than 10⁻⁵ Torr during transferring.

The reaction space, for example reaction space volume 134, can be purged after a batch is processed therein to remove any process gases and by-products from the reaction space. An inert gas can be used as a purge gas to displace any reactive process vapors and volatile by-product remaining in the reaction space after processing the substrates. In some implementations, a vacuum pump can be used to decrease the pressure in the reaction space prior to opening the reactor space to the surrounding process chamber space.

It is faster to pump down the smaller volume of the reaction space 134 than it is to pump down the larger internal volume 132 of the process chamber 116. The internal volume 132 of the process chamber 116 can be maintained at a lower pressure than the processing pressure used in the reaction space 134 during processing. Thus, the time to reduce the pressure in the reaction space 134 prior to opening the shell 130 and unloading the substrates is shortened in comparison to the time that it would take to reduce the pressure in the larger process chamber internal volume 134. The transfer chamber 114 can also be maintained at pressure similar to the pressure used in the process chamber 116.

The process gases used in the different processes, such as the etch/release, ALD layer formation and SAM formation, can react together to form undesired by-products and/or be incompatible with the materials used for the reaction space and process chambers that perform the other processes. Purging of the reaction spaces can reduce the risk of cross contamination and avoid the formation of undesirable by-products formed by mixing process gases used in the different processes.

In another implementation the transfer chamber 114 can be maintained at a higher pressure than the internal volumes 132 of the process chambers 116 and the reaction spaces 134. An inert gas, such as nitrogen, can be provided to the transfer chamber 114 to maintain a pressure higher than the process chambers. The positive pressure in the transfer chamber 114 can prevent diffusion or the flow of gases from the process chamber to the transfer chamber to decrease the likelihood of cross contamination of process gases between the different process chambers and reaction spaces. Unlike the opposite pressure gradient, which can prevent flow into the reaction spaces, employing a higher pressure in the transfer chamber 114 can prevent interaction between residual process gases of different processes and thus prevent cross-contamination. In some implementations a high vacuum (low pressure) is used in the transfer chamber, process chamber, and reaction space. The high vacuum pressure can result in decreased molecules in the chambers and decrease the chance of cross contamination because of the lower numbers of molecules present in the chambers.

In some implementations the batch cluster tool can be used to process multiple substrates simultaneously, and to sequentially perform release/etch, ALD of an antistiction layer, and vapor deposition of antistiction SAM. An example of sequential processing will be described with reference to FIG. 12 for describing movement among the chambers of a batch cluster tool 150, along with reference to FIG. 15B for describing parts of individual process chambers. Multiple substrates can be loaded into a load lock chamber 153. The substrates can be transferred from the load lock chamber 153 into transfer chamber 151 and into a first processing chamber 154a by the robot 152. The robot 152 can transfer one or more substrates at a time. After multiple substrates are loaded in the first process chamber 154a, the platform 128 can be engaged with the reactor shell 130 to form the reaction space 134 inside the first process chamber 154a. The multiple substrates can be exposed to an etchant, such as XeF₂, to etch a portion of the substrates to form a cavity, for example 19 (FIG. 8E). After etching the substrates, a purge gas can be used to purge the reaction space 134 followed by the use of a vacuum pump to decrease the reaction space pressure to a pressure that can be about the same as the pressure in the surrounding process chamber interior volume 132. The platform 128 can be lowered and the substrates can be transferred from the first process chamber 154a into the transfer chamber 151 and into a second process chamber 154b by the transfer robot 152. After the substrates are transferred out of the first process chamber 154a, a new batch of substrates can be transferred into the first process chamber 154a and processed.

After the substrates can be transferred into the second process chamber 154b, the platform 128 in the second process chamber 154b can be raised to engage with the reactor shell 130 in the second process chamber 154b. An ALD process can be conducted therein. For example a metal source vapor and an oxidant source vapor can be alternated to form an antistiction layer in the cavity left by the release/etch by ALD. In one implementation, TMA and water can be alternately and sequentially supplied to the multiple substrates to form aluminum oxide within the cavity formed during the etch process. The pulses of TMA and water can be separated by purge periods of flowing inert purge gas. After formation of the aluminum oxide layer the reaction space can be purged and a vacuum pump can be used to decrease the pressure in the reaction space to a pressure that can be about the same as the pressure in the surrounding process chamber. The platform 128 can be lowered and the substrates can be transferred from the second process chamber 154b into the transfer chamber 151 and into a third process chamber 154c by the transfer robot 152. After the substrates are transferred out of the second process chamber 154b, a new batch of substrates can be transferred into the second process chamber 154b and processed.

After the substrates are transferred into the third process chamber 154c, the platform 128 in the third process chamber 154c is raised to engage with the reactor shell 130 in the third process chamber 154c. An antistiction self-assembled monolayer (SAM) can be formed in the third chamber 154c over the antistiction layer left by the ALD process. In one implementation N-decyltrichlorosilane and water can be used to form the SAM layer on the aluminum oxide layers formed in the cavities on the substrates. After formation of the SAM the reaction space can be purged and a vacuum pump can be used to decrease the pressure in the reaction space 134 to a pressure that is about the same as the pressure in the surrounding process chamber interior volume 132. The platform 128 can be lowered and the substrates can be transferred from the third process chamber 154c into the transfer chamber 151 and into the load lock chamber 153 or another process chamber for further processing. After the substrates are transferred out of the third process chamber 154c, a new batch of substrates (such as from the second process chamber 154b) can be transferred into the third process chamber 154c and processed.

FIG. 8F shows an example of an IMOD having a cavity 19 with an ALD layer 31a and a SAM layer 31b lining all surfaces of the cavity 19.

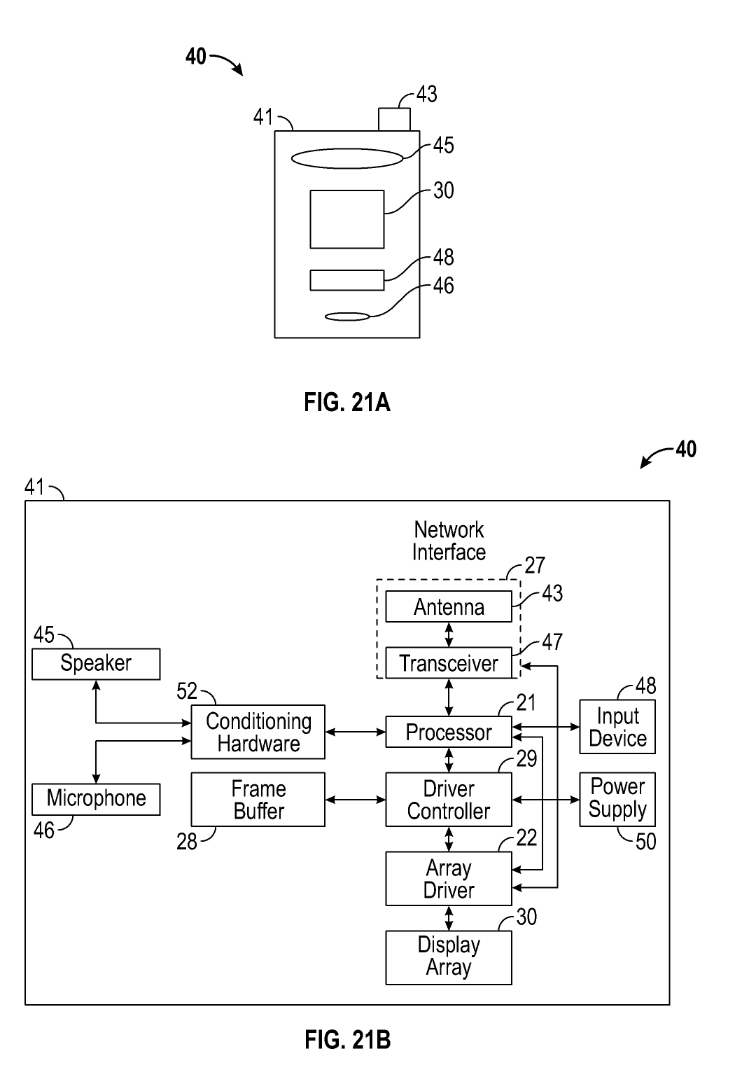

FIGS. 21A and 21B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 21B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), NEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. In some implementations the methods illustrated in FIGS. 9 and 10 can be implemented in software and stored on or transmitted over as one or more instructions or code on a computer-readable medium that can be associated with a controller, such as the controller 115 of FIG. 11. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product. Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus for processing substrates, comprising:
a process chamber configured to process multiple substrates, wherein the process chamber comprises a plurality of stacked individual subchambers, each subchamber configured to process one substrate;
a common reactant source configured to selectively provide a reactant to each of the subchambers in parallel; and
a common exhaust pump selectively connected to each of the subchambers.

2. A cluster tool comprising two or more of the apparatus of claim 1, comprising at least two of:
a first processing chamber comprising a first plurality of subchambers in fluid communication with a common etchant source including a fluorine based etchant;
a second processing chamber comprising a second plurality of subchambers in fluid communication with a common source of atomic layer deposition reactants, including a first common oxidizing source and a second common source including one of a semiconductor and a metal source; and
a third processing chamber comprising a third plurality of subchambers in fluid communication with a common source of reactant to form a self-assembled monolayer (SAM).

3. The cluster tool of claim 2, wherein the first processing chamber is configured to provide a volume-controlled dose of the fluorine based etchant into the first plurality of subchambers, and wherein the third processing chamber is configured to provide a pressure-controlled dose of the reactant to form the SAM into the third plurality of subchambers.

4. The apparatus of claim 1, further comprising:
an accumulator positioned downstream of the common reactant source and upstream of the subchambers; and
a plurality of outlet valves positioned downstream of the accumulator, each outlet valve configured to selectively flow reactant from the accumulator into one of the subchambers.

5. The apparatus of claim 4, wherein the accumulator comprises a plurality of buffers, wherein at least one buffer is positioned upstream of each outlet valve, further comprising a plurality of inlet valves, each inlet valve positioned upstream of and configured to selectively flow reactant into each of the buffers.

6. The apparatus of claim 5, wherein the common reactant source comprises a first reactant source and a second reactant source in parallel with respect to each other, the plurality of buffers comprising a first buffer positioned downstream of the first reactant source and upstream of each subchamber, and a second buffer positioned downstream of the second reactant source and upstream of each subchamber.

7. The apparatus of claim 6, wherein the first reactant source and the second reactant source comprise sources of reactants to form a self-assembled monolayer (SAM).

8. The apparatus of claim 7, wherein the first reactant source comprises an organic source chemical, and the second reactant source comprises an oxygen source.

9. The apparatus of claim 8, further comprising a control system configured to close at least one of the outlet valves and open at least one of the inlet valves to allow flow into at least one of the first and second buffer from the first and second reactant source, respectively, until pressure within the buffer reaches a threshold, after which the inlet valve is closed, and the outlet valve is opened, to flow a pressure-controlled dose of reactant from the first or second buffer into at least one subchamber.

10. The apparatus of claim 9, wherein the first reactant source comprises an n-decyltrichlorosilane (DTS) source and the second reactant source comprises a water source, wherein the control system is configured to provide a pressure-controlled dose of DTS to at least one subchamber from the first buffer within a range of approximately 0.3 to 0.5 Torr and provide a pressure-controlled dose of water to the at least one subchamber from the second buffer within a range of approximately 25-37 Torr.

11. The apparatus of claim 10, wherein at least one of the inlet valve positioned upstream of the second buffer and the outlet valve positioned upstream of the second buffer has a response time within a range of approximately 5-30 ms.

12. The apparatus of claim 4, wherein the common reactant source comprises a common source of atomic layer deposition reactants, including a common source including one of a semiconductor and a metal source, and the accumulator comprises a primary conduit with an inner cross-sectional area that falls within a range of approximately 2 to 8 times greater than an inner cross-sectional area of each of a plurality of secondary conduits leading from the primary conduit to the subchambers.

13. The apparatus of claim 1, further comprising a reactant distribution manifold configured to provide fluid communication between the common source of reactant and each of the subchambers, wherein the reactant distribution manifold comprises:
a primary conduit connected to the common source of reactant;
a first connection point at a downstream end of the primary conduit, the first connection point dividing flow from the primary conduit into two secondary conduits;
a plurality of second connection points at downstream ends of the secondary conduits, each second connection point dividing flow from the corresponding secondary conduit into two tertiary conduits; and
a plurality of third connection points at downstream ends of the tertiary conduits, each third connection point dividing flow from the corresponding tertiary conduit into two quaternary conduits;
wherein the reactant distribution manifold comprises one first connection point, two second connection points, and four third connection points, for a total of two secondary conduits, four tertiary conduits, and eight quaternary conduits in communication with eight subchambers, wherein flow paths from the common source of reactant to each of the eight subchambers are approximately equal.

14. The apparatus of claim 1, wherein each subchamber comprises:
a substrate support comprising a base, a lift pin seat recessed with respect to an upper surface of the base, and a plurality of pin holes extending through the lift pin seat and the base, each pin hole comprising a tapered opening facing the upper surface of the base;
a plurality of self-centering lift pin assemblies, each configured to extend through one of the pin holes, each lift pin assembly comprising a lift pin shaft, and a pin head with a tapered surface configured to face the tapered opening of the corresponding pin hole when the lift pin assembly extends through the corresponding pin hole; and
a lift pin support configured to support the lift pin assemblies.

15. The apparatus of claim 14, further comprising one or more heaters configured to control the temperature of the lift pin support.

16. The apparatus of claim 14, further comprising a movable element attached to and configured to allow relative lateral movement between the lift pin shaft of each lift pin assembly and the lift pin support.

17. An apparatus for processing electromechanical systems devices, comprising:
a process chamber configured to process multiple substrates, comprising a means for isolating the process chamber into a plurality of stacked individual subchambers, each subchamber configured to process one substrate;
a means for selectively providing a common reactant to each of the subchambers; and
a common means for selectively exhausting each of the subchambers.

18. A cluster tool comprising two or more of the apparatus of claim 17, comprising at least two of:
a first processing chamber comprising a first plurality of subchambers, including means for removing sacrificial layers from the substrates;
a second processing chamber comprising a second plurality of subchambers, including means for forming an ALD layer on the substrates; and
a third processing chamber comprising a third plurality of subchambers, including means for forming a self-assembled monolayer (SAM) on the substrates.

19. The cluster tool of claim 18, wherein the first processing chamber is configured to provide a volume-controlled dose of the fluorine based etchant into the first plurality of subchambers, and wherein the third processing chamber is configured to provide a pressure-controlled dose of the reactant to form the SAM into the third plurality of subchambers.

20. The apparatus of claim 17, further comprising:
a means for accumulating a volume of reactant positioned downstream of the common reactant means and upstream of the subchambers; and
a first plurality of means for selectively flowing reactant from the accumulating means into one of the subchambers.

21. The apparatus of claim 20, wherein the accumulating means comprises a plurality of buffers, wherein at least one buffer is positioned upstream of each first means for selectively flowing reactant, further comprising a second plurality of means positioned upstream of and configured to selectively flow reactant into each of the buffers.

22. The apparatus of claim 21, wherein the common reactant means comprises a first reactant source including an organic source chemical and a second reactant source comprising an oxygen source, the first and second reactant source in parallel with respect to each other, the plurality of buffers comprising a first buffer positioned downstream of the first reactant source and upstream of each subchamber, and a second buffer positioned downstream of the second reactant source and upstream of each subchamber.

23. The apparatus of claim 22, further comprising means for flowing a pressure-controlled dose of reactant from the first or second buffer into at least one subchamber.

24. The apparatus of claim 17, further comprising means for distributing reactant between the common source of reactant and each of the subchambers, the reactant distributing means comprising:
a primary conduit connected to the common source of reactant;
a first connection point at a downstream end of the primary conduit, the first connection point dividing flow from the primary conduit into two secondary conduits;
a plurality of second connection points at downstream ends of the secondary conduits, each second connection point dividing flow from the corresponding secondary conduit into two tertiary conduits; and
a plurality of third connection points at downstream ends of the tertiary conduits, each third connection point dividing flow from the corresponding tertiary conduit into two quaternary conduits;
wherein the reactant distribution manifold comprises one first connection point, two second connection points, and four third connection points, for a total of two secondary conduits, four tertiary conduits, and eight quaternary conduits in communication with eight subchambers, wherein flow paths from the common source of reactant to each of the eight subchambers are approximately equal.

25. The apparatus of claim 17, wherein each subchamber comprises:
means for supporting a substrate comprising a base, a lift pin seat recessed with respect to an upper surface of the base, and a plurality of pin holes extending through the lift pin seat and the base, each pin hole comprising a tapered opening facing the upper surface of the base;
a plurality of self-centering means for lifting a substrate, each substrate lifting means configured to extend through one of the pin holes, each substrate lifting means comprising a lift pin shaft, and a pin head with a tapered surface configured to face the tapered opening of the corresponding pin hole when the substrate lifting means extends through the corresponding pin hole; and
a lift pin support configured to support the substrate lifting means.

26. The apparatus of claim 25, further comprising one or more means for controlling the temperature of the lift pin support.

27. The apparatus of claim 25, further comprising means for providing relative lateral movement between the lift pin shaft of each substrate lifting means and the lift pin support.

28. A method of processing substrates, comprising:
transferring multiple substrates into a process chamber, wherein the process chamber comprises a plurality of stacked individual subchambers, each subchamber configured to process one substrate;
exposing the substrates to a reactant provided from a reactant source commonly connected to each of the subchambers; and
exhausting the reactant from the subchambers through an exhaust commonly and selectively connected to each of the subchambers.

29. A method comprising performing the method of claim 28 in two or more process chambers, wherein exposing the substrates to the reactant comprises two or more of:
exposing the substrates to a vapor phase etchant;
exposing the substrates to vapor phase reactants to form a thin film on the substrates by ALD, and
exposing the substrates to vapor phase reactants to form a self-assembled monolayer (SAM) on the substrates.

30. The method of claim 29, wherein exposing the substrates to a vapor phase etchant comprises providing a volume-controlled dose of the vapor phase etchant into a first plurality of subchambers within a first process chamber, and wherein exposing the substrates to vapor phase reactants comprises providing a pressure-controlled dose of the vapor phase reactants into a second plurality of subchambers within a second process chamber.

31. The method of claim 28, further comprising:
flowing reactant from the reactant source into an accumulator positioned upstream of the subchambers; and
selectively flowing reactant from the accumulator into one of the subchambers through a plurality of outlet valves, each valve positioned downstream of the accumulator and upstream of each subchamber.

32. The method of claim 31, wherein flowing reactant from the reactant source into the accumulator comprises selectively flowing reactant into a plurality of buffers positioned upstream of each subchamber through a plurality of inlet valves, each inlet valve positioned upstream of each of the buffers.

33. The method of claim 32, wherein flowing reactant into the plurality of buffers comprises flowing reactant from a first reactant source into a first plurality of buffers, and flowing reactant from a second reactant source into a second plurality of buffers, the first reactant source and first plurality of buffers in parallel with respect to the second reactant source and second plurality of buffers.

34. The method of claim 33, wherein flowing reactant from the first reactant source and the second reactant source comprises flowing reactants for forming a self-assembled monolayer (SAM).

35. The method of claim 34, wherein the first reactant source comprises an organic source chemical, and the second reactant source comprises an oxygen source.

36. The method of claim 35, further comprising providing a pressure-controlled dose of reactant into at least one subchamber, comprising:
closing at least one of the outlet valves;
opening at least one of the inlet valves while the at least one outlet valve is closed;
flowing reactant into at least one of the first and second buffer from the first and second reactant source, respectively;
closing the inlet valve after pressure within the buffer reaches a pressure threshold;
opening the outlet valve while the inlet valve is closed, to flow a pressure-controlled dose of reactant from the first or second buffer into at least one subchamber.

37. The method of claim 36, wherein the first reactant source comprises an n-decyltrichlorosilane (DTS) source and the second reactant source comprises a water source, wherein providing the pressure-controlled dose of reactant comprises providing DTS to at least one subchamber from the first buffer within a range of approximately 0.3 to 0.5 Torr and providing a pressure-controlled dose of water to the at least one subchamber from the second buffer within a range of approximately 25-37 Torr.

38. The method of claim 31, wherein flowing reactant comprises flowing reactant through a primary conduit of the accumulator, the primary conduit having an inner cross-sectional area that falls within a range of approximately 2 to 8 times greater than an inner cross-sectional area of each of a plurality of secondary conduits leading from the primary conduit to the subchambers, wherein the reactant source comprises a common source of atomic layer deposition reactants, including a common source including one of a semiconductor and a metal source.

39. The method of claim 28, further comprising:
flowing the reactant through a primary conduit connected to the common source of reactant;
dividing the reactant flow from the primary conduit into two secondary conduits through a first connection point positioned at a downstream end of the primary conduit;
dividing the reactant flow from each secondary conduit into two tertiary conduits through second connection points positioned at a downstream end of each secondary conduit; and
dividing the reactant flow from each tertiary conduit into at least two quaternary conduits through third connection points at a downstream ends of each tertiary conduit;
wherein flow paths from the common source of reactant to each of the eight subchambers are approximately equal.

40. The method of claim 28, further comprising:
providing a process subchamber comprising:
a substrate support comprising a plurality of pin holes extending through a corresponding plurality of lift pin seats; and
a plurality of self-centering lift pin assemblies supported by a lift pin support, each lift pin assembly comprising a lift pin shaft and a pin head with a tapered surface; and
extending the lift pin assemblies through the corresponding lift pin seats and pin holes of the substrate support, such that the tapered surface of the pin head is surrounded by a corresponding tapered opening in each of the pin holes.

41. The method of claim 40, further comprising controlling the temperature of the lift pin support with a heater.

42. The method of claim 40, further comprising laterally moving the lift pin shaft of each lift pin assembly relative to the lift pin support.

43. The method of claim 28, further comprising selectively taking one or more of the subchambers off-line, while still allowing continued processing of substrates in the remaining subchambers in parallel.

44. A method of processing substrates, comprising:
transferring multiple substrates into a process chamber, wherein the process chamber comprises a plurality of stacked individual subchambers, each subchamber configured to process one substrate;
closing an outlet valve connected upstream of a first subchamber and downstream of a buffer;
opening an inlet valve positioned upstream of the buffer;
flowing reactant from a reactant source through the inlet valve and into the buffer;
closing the inlet valve after pressure within the buffer reaches a pressure threshold;
opening the outlet valve while the inlet valve is closed, to flow a pressure-controlled dose of reactant from the buffer into the first subchamber.
